(19) United States
(12) Patent Application Publication
(10) Pub. No.: US 2025/0366013 A1
(43) Pub. Date: Nov. 27, 2025

(54) INTEGRATED CIRCUIT DEVICE

(71) Applicant: SAMSUNG ELECTRONICS CO., LTD., Suwon-si (KR)

(72) Inventors: Jeonghyeon Lee, Suwon-si (KR); Minseok Jo, Suwon-si (KR); Hyungkoo Kang, Suwon-si (KR); Jonghan Lee, Suwon-si (KR)

(73) Assignee: SAMSUNG ELECTRONICS CO., LTD., Suwon-si (KR)

(21) Appl. No.: 18/974,239

(22) Filed: Dec. 9, 2024

(30) Foreign Application Priority Data
May 22, 2024 (KR) 10-2024-0066595

(51) Int. Cl. H10D 30/00; H10D 30/01; H10D 62/10; H10D 64/23; H10D 64/66; H10D 84/83

(52) U.S. Cl. CPC H10D 30/508; H10D 30/0198; H10D 62/116; H10D 64/2565; H10D 62/121; H10D 64/668; H10D 84/832

(57) ABSTRACT

An integrated circuit device includes a first gate line and a second gate line adjacent to each other in a first horizontal direction and extending in a second horizontal direction that is perpendicular to the first horizontal direction, a source/drain region between the first gate line and the second gate line, a backside via contact connected to the source/drain region, and a first backside bulk insulating film and a second backside bulk insulating film, where, in the first horizontal direction, the backside via contact is between the first backside bulk insulating film and the second backside bulk insulating film, where each of the first backside bulk insulating film and the second backside bulk insulating film includes a vertical insulating portion below one gate line among the first gate line and the second gate line in a vertical direction and extending in the vertical direction.

### CROSS-REFERENCE TO RELATED APPLICATION

This application is based on and claims priority to Korean Patent Application No. 10-2024-0066595, filed on May 22, 2024, in the Korean Intellectual Property Office, the disclosure of which is incorporated by reference herein in its entirety.

### BACKGROUND

Example embodiments of the disclosure relate to an integrated circuit device, and more particularly, to an integrated circuit device including a backside contact structure.

Due to the advance of electronics technology, integrated circuit devices have been rapidly down-scaled. Because highly down-scaled integrated circuit devices require high operation speeds as well as accuracy in operations, there is a need for techniques to provide a wiring structure including conductive lines, which are arranged in a stable and optimized structure in a relatively small area, and to prevent an unintended short-circuit between a plurality of conductive regions.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an integrated circuit device having a structure including a plurality of wiring structures arranged in a reduced area due to down-scaling, which may be capable of preventing the generation of unintended leakage current between conductive regions in an integrated circuit device, and of securing the reliability of the integrated circuit device.

Additional aspects will be set forth in part in the description which follows and, in part, will be apparent from the description, or may be learned by practice of the presented embodiments.

According to an aspect of an example embodiment, an integrated circuit device may include a first gate line and a second gate line adjacent to each other in a first horizontal direction and extending in a second horizontal direction that is perpendicular to the first horizontal direction, a source/drain region between the first gate line and the second gate line, a backside via contact connected to the source/drain region, and a first backside bulk insulating film and a second backside bulk insulating film, where, in the first horizontal direction, the backside via contact is between the first backside bulk insulating film and the second backside bulk insulating film, where each of the first backside bulk insulating film and the second backside bulk insulating film includes a vertical insulating portion below one gate line among the first gate line and the second gate line in a vertical direction and extending in the vertical direction, the vertical insulating portion including a portion facing the backside via contact in the first horizontal direction, and a horizontal insulating portion protruding from a sidewall of the vertical insulating portion in the first horizontal direction and contacting the source/drain region.

According to an aspect of an example embodiment, a first source/drain region and a second source/drain region adjacent to each other in a first horizontal direction, a plurality of nanosheets between the first source/drain region and the second source/drain region, each of the plurality of nanosheets being spaced apart from each other in a vertical direction being connected to the first source/drain region and the second source/drain region, a gate line extending in a second horizontal direction between the first source/drain region and the second source/drain region and surrounding the plurality of nanosheets, the second horizontal direction being perpendicular to the first horizontal direction, a gate dielectric film between the plurality of nanosheets and the gate line and surrounding the gate line, a backside via contact connected to the first source/drain region, and a backside bulk insulating film between the first source/drain region and the second source/drain region and spaced apart from the gate line in the vertical direction, where the gate dielectric film is between the backside bulk insulating film and the gate line in the vertical direction, and where the backside bulk insulating film includes a vertical insulating portion below the gate line in the vertical direction and extending in the vertical direction, the vertical insulating portion including a portion facing the backside via contact in the first horizontal direction, and a first horizontal insulating portion and a second horizontal insulating portion respectively protruding from a first sidewall and a second sidewall of the vertical insulating portion in the first horizontal direction.

According to an aspect of an example embodiment, an integrated circuit device may include a plurality of backside bulk insulating films arranged in a line in a first horizontal direction and each extending in a second horizontal direction that is perpendicular to the first horizontal direction, a plurality of nanosheet stacks respectively spaced apart from the plurality of backside bulk insulating films in a vertical direction, each of the plurality of nanosheet stacks including a plurality of nanosheets, a plurality of gate lines extending in the second horizontal direction and respectively surrounding the plurality of nanosheets, a plurality of source/drain regions respectively between the plurality of gate lines, each of the plurality of source/drain regions contacting the plurality of nanosheets of an adjacent nanosheet stack among the plurality of nanosheet stacks, a plurality of backside wiring structures respectively between the plurality of backside bulk insulating films, and a plurality of gate dielectric films respectively surrounding the plurality of gate lines, where each of the plurality of backside bulk insulating films may include a vertical insulating portion contacting adjacent backside wiring structures among the plurality of backside wiring structures, the vertical insulating portion extending in the vertical direction toward respective gate line from the plurality of gate lines, and a first horizontal insulating portion and a second horizontal insulating portion respectively protruding from a first sidewall and a second sidewall of the vertical insulating portion in the first horizontal direction, and where each of the plurality of backside bulk insulating films includes a nitrogen-containing insulating film.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating an example of a cell block of an integrated circuit device according to one or more embodiments;

FIG. 2 is a diagram illustrating an integrated circuit device according to one or more embodiments;

FIG. 3A is a cross-sectional view of the integrated circuit device of FIG. 2, taken along a line X1-X1′ of FIG. 2 according to one or more embodiments;

FIG. 3B is a cross-sectional view of the integrated circuit device of FIG. 2, taken along a line Y1-Y1′ of FIG. 2 according to one or more embodiments;

FIG. 3C is a cross-sectional view of the integrated circuit device of FIG. 2, taken along a line Y2-Y2′ of FIG. 2 according to one or more embodiments;

FIG. 4 is an enlarged cross-sectional view of a region EX1 of FIG. 3A according to one or more embodiments;

FIGS. 5 to 8 are cross-sectional views respectively illustrating integrated circuit devices according to one or more embodiments; and

FIGS. 9A to 26B are diagrams respectively illustrating a method of fabricating an integrated circuit device, according to one or more embodiments

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

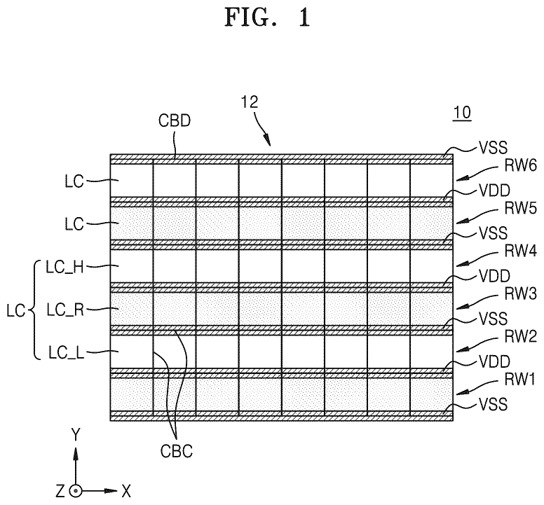

FIG. 1 is a plan view illustrating an example of a cell block 12 of an integrated circuit device 10 according to one or more embodiments.

Referring to FIG. 1, the cell block 12 of the integrated circuit device 10 may include a plurality of cells LC including circuit patterns that constitute various circuits. The plurality of cells LC may be arranged in a matrix in a width direction (an X direction in FIG. 1) and a length direction (a Y direction in FIG. 1) in a cell block 12.

The plurality of cells LC may include a circuit pattern having a layout designed by a Place and Route (PnR) technique to perform at least one logical function. The plurality of cells LC may perform various logical functions. In one or more embodiments, the plurality of cells LC may include a plurality of standard cells. In one or more embodiments, at least some of the plurality of cells LC may perform the same logical function. In one or more embodiments, at least some of the plurality of cells LC may perform different logical functions from each other.

The plurality of cells LC may include various types of logic cells including a plurality of circuit elements. For example, each of the plurality of cells LC may include, but is not limited to, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, or a combination thereof.

In the cell block 12, at least some of the plurality of cells LC constituting one row (that is, RW1, RW2, RW3, RW4, RW5, or RW6) in the width direction (the X direction in FIG. 1) may have the same width. In addition, at least some of the plurality of cells LC constituting one row (that is, RW1, RW2, RW3, RW4, RW5, or RW6) may each have the same height. However, embodiments are not limited to the example shown in FIG. 1, and at least some of the plurality of cells LC constituting one row (that is, RW1, RW2, RW3, RW4, RW5, or RW6) may have different widths and heights from each other.

The area of each of the plurality of cells LC in the cell block 12 of the integrated circuit device 10 may be defined by a cell boundary CBD. A cell interface portion CBC, at which respective cell boundaries CBD meet each other, may be arranged between two adjacent cells LC in the width direction (the X direction in FIG. 1) or the height direction (the Y direction in FIG. 1) from among the plurality of cells LC.

In one or more embodiments, two adjacent cells LC in the width direction, among the plurality of cells LC constituting one row (that is, RW1, RW2, RW3, RW4, RW5, or RW6), may contact each other at the cell interface portion CBC without a separation distance therebetween. In one or more embodiments, two adjacent cells LC in the width direction, among the plurality of cells LC constituting one row (that is, RW1, RW2, RW3, RW4, RW5, or RW6), may be spaced apart from each other with a predefined separation distance therebetween.

In one or more embodiments, in the plurality of cells LC constituting one row (that is, RW1, RW2, RW3, RW4, RW5, or RW6), two adjacent cells LC may perform the same function. In this case, the two adjacent cells LC may have the same structure. In one or more embodiments, in the plurality of cells LC constituting one row (that is, RW1, RW2, RW3, RW4, RW5, or RW6), two adjacent cells LC may respectively perform different functions.

In one or more embodiments, one cell LC among the plurality of cells LC, which are included in the cell block 12 of the integrated circuit device 10, and another cell LC adjacent to the cell LC in the length direction (the Y direction in FIG. 1) may have symmetric structures about the cell interface portion CBC therebetween. For example, a reference logic cell LC_R in a third row RW3 and a lower logic cell LC_L in a second row RW2 may have symmetric structures about the cell interface portion CBC therebetween. In addition, the reference logic cell LC_R in the third row RW3 and an upper logic cell LC_H in a fourth row RW4 may have symmetric structures about the cell interface portion CBC therebetween. Although FIG. 1 illustrates the cell block 12 including six rows (that is, RW1, RW2, RW3, RW4, RW5, and RW6), this is only an example, and the cell block 12 may include rows in various numbers as needed, and one row may include logic cells in various numbers as needed.

One from among a plurality of ground lines VSS and a plurality of power lines VDD may be arranged between a plurality of rows (that is, RW1, RW2, RW3, RW4, RW5, and RW6), which each include the plurality of cells LC arranged in a line in the width direction (the X direction in FIG. 1). The plurality of ground lines VSS and the plurality of power lines VDD may each extend in a first horizontal direction (the X direction) and may be alternately arranged apart from each other in a second horizontal direction (the Y direction). Therefore, each of the plurality of ground lines VSS and the plurality of power lines VDD may be arranged to overlap the cell boundary CBD of the cell LC, the cell boundary CBD extending in the second horizontal direction (the Y direction).

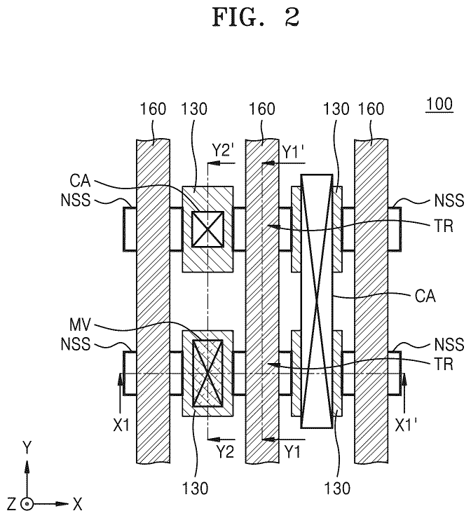

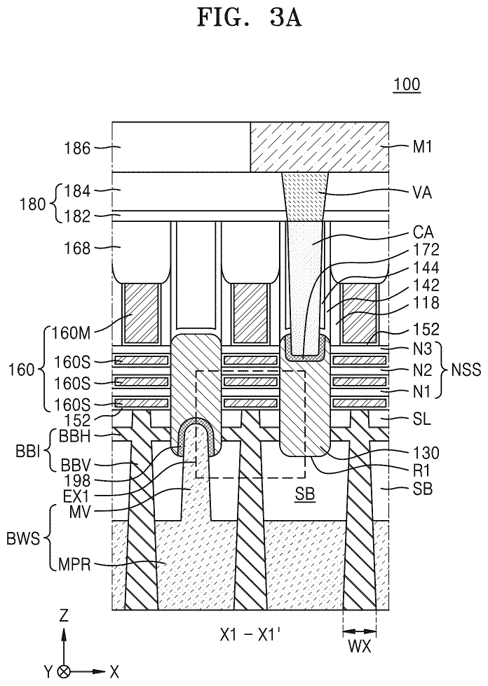

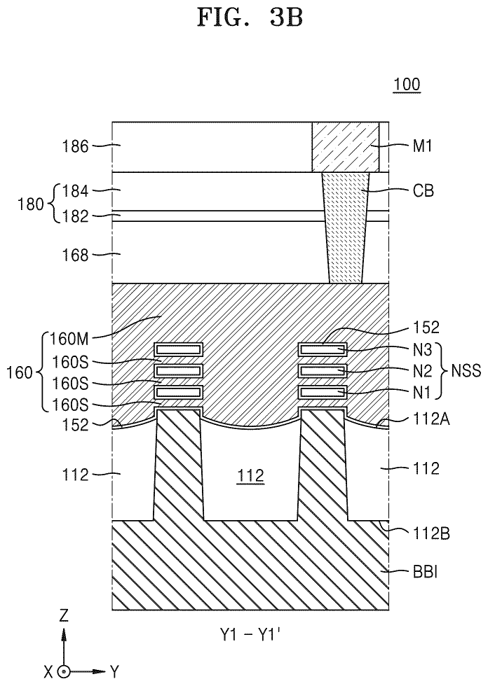

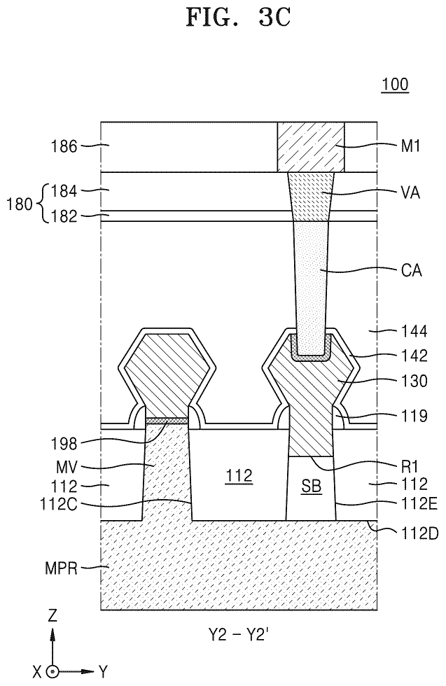

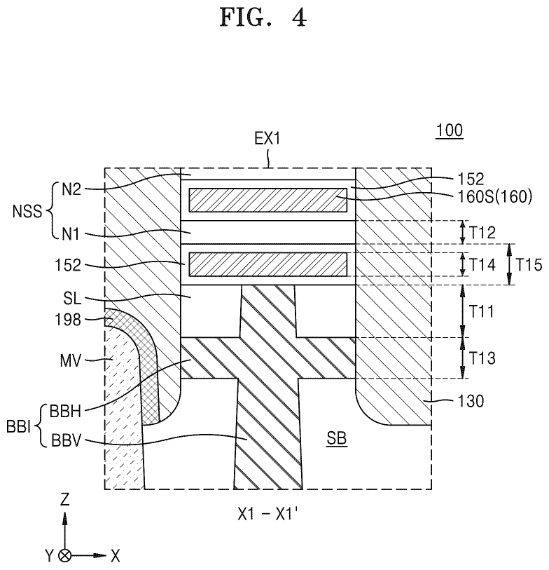

FIG. 2 is a diagram illustrating an integrated circuit device 100 according to one or more embodiments. FIG. 3A is a cross-sectional view of the integrated circuit device 100, taken along a line X1-X1′ of FIG. 2 according to one or more embodiments. FIG. 3B is a cross-sectional view of the integrated circuit device 100, taken along a line Y1-Y1′ of FIG. 2 according to one or more embodiments. FIG. 3C is a cross-sectional view of the integrated circuit device 100, taken along a line Y2-Y2′ of FIG. 2 according to one or more embodiments. FIG. 4 is an enlarged cross-sectional view of a region EX1 of FIG. 3A according to one or more embodiments.

The integrated circuit device 100 including a field-effect transistor, which has a gate-all-around (GAA) structure including a nanowire or nanosheet-shaped active region and a gate surrounding the active region, is described with reference to FIGS. 2, 3A to 3C, and 4. The components shown in FIGS. 2, 3A to 3C, and 4, in the integrated circuit device 100, may constitute a portion of the plurality of cells LC shown in FIG. 1.

Referring to FIGS. 2, 3A to 3C, and 4, the integrated circuit device 100 may include a plurality of backside bulk insulating films BBI, which are arranged in a line in the first horizontal direction (the X direction) and each extend lengthwise in the second horizontal direction (the Y direction) that is perpendicular to the first horizontal direction (the X direction), and a plurality of backside wiring structures BWS separated from each other in the first horizontal direction (the X direction) by the plurality of backside bulk insulating films BBI. As shown in FIG. 3A, the plurality of backside wiring structures BWS may be arranged one-by-one between each of the plurality of backside bulk insulating films BBI in the first horizontal direction (the X direction).

The integrated circuit device 100 may include a plurality of nanosheet stacks NSS, which are arranged to be spaced apart from the plurality of backside bulk insulating films BBI in a vertical direction (a Z direction), and each of the plurality of nanosheet stacks NSS may include a first nanosheet N1, a second nanosheet N2, and a third nanosheet N3. A plurality of gate lines 160 may each surround the first nanosheet N1, the second nanosheet N2, and the third nanosheet N3 and may extend lengthwise in the second horizontal direction (the Y direction). Herein, each of the first nanosheet N1, the second nanosheet N2, and the third nanosheet N3 may be referred to as a channel region. The plurality of gate lines 160 may be spaced apart from each other in the first horizontal direction (the X direction) and may extend lengthwise in the second horizontal direction (the Y direction). Each of the plurality of gate lines 160 may be surrounded by a gate dielectric film 152.

The integrated circuit device 100 may include a plurality of source/drain regions 130 arranged one-by-one between each of the plurality of gate lines 160. Each of the plurality of source/drain regions 130 may contact the first nanosheet N1, the second nanosheet N2, and the third nanosheet N3, which are included in a nanosheet stack NSS adjacent thereto.

Each of the plurality of backside bulk insulating films BBI may include a vertical insulating portion BBV and a pair of horizontal insulating portions BBH protruding from both sidewalls of the vertical insulating portion BBV in the first horizontal direction (the X direction). The vertical insulating portion BBV may contact a pair of backside wiring structures BWS among the plurality of backside wiring structures BWS and that are adjacent to each other. The vertical insulating portion BBV may extend lengthwise in the vertical direction (the Z direction) from a space between the pair of backside wiring structures BWS adjacent to each other toward one gate line 160 among the plurality of gate lines 160. Each of the pair of horizontal insulating portions BBH, which are included in each of the plurality of backside bulk insulating films BBI, may contact a source/drain region 130 adjacent thereto from among the plurality of source/drain regions 130. In one or more embodiments, each of the plurality of backside bulk insulating films BBI may include a nitrogen-containing insulating film. For example, each of the plurality of backside bulk insulating films BBI may include, but is not limited to, a silicon nitride (SiN) film, a silicon carbonitride (SiCN) film, a silicon oxycarbonitride (SiOCN) film, or a combination thereof.

As shown in FIG. 3A, the plurality of backside wiring structures BWS may include a backside via contact MV and a plurality of backside power rails MPR. The backside via contact MV may be integrally connected to one backside power rail MPR among the plurality of backside power rails MPR.

The backside via contact MV may extend lengthwise in the vertical direction (the Z direction) between a pair of backside bulk insulating films BBI adjacent to each other from among the plurality of backside bulk insulating films BBI. The backside via contact MV may be configured to be connected to a first source/drain region among the plurality of source/drain regions 130.

A backside power rail MPR integrally connected to the backside via contact MV, among the plurality of backside power rails MPR, may be spaced apart from a source/drain region 130 in the vertical direction (the Z direction) with the backside via contact MV therebetween. As shown in FIG. 3C, the plurality of backside power rails MPR may extend lengthwise in the second horizontal direction (the Y direction).

In one or more embodiments, the backside via contact MV and the backside power rail MPR may be simultaneously formed in a single process and may include the same material. In one or more embodiments, the backside via contact MV and the backside power rail MPR may be respectively formed by separate processes, and there may be an interface between the backside via contact MV and the backside power rail MPR. In one or more embodiments, the backside via contact MV and the backside power rail MPR may include a single metal. In one or more embodiments, the backside via contact MV and the backside power rail MPR may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. The conductive barrier film may include a metal or a conductive metal nitride. For example, the conductive barrier film may include, but is not limited to, Ti, Ta, W, TIN, TaN, WN, WCN, TiSiN, TaSiN, WSiN, or a combination thereof.

The vertical insulating portion BBV of each of the plurality of backside bulk insulating films BBI may include a portion contacting the backside power rail MPR and may be spaced apart from the backside via contact MV in the first horizontal direction (the X direction). The plurality of backside bulk insulating films BBI may include a pair of backside bulk insulating films BBI arranged one-by-one on both sides of the backside via contact MV with the backside via contact MV therebetween in the first horizontal direction (the X direction). Each of the pair of backside bulk insulating films BBI may be located below one gate line 160 among the plurality of gate lines 160 in the vertical direction (the Z direction) and may extend lengthwise in the vertical direction (the Z direction). The vertical insulating portion BBV of each of the pair of backside bulk insulating films BBI may include a portion facing the backside via contact MV in the first horizontal direction (the X direction). In each of the pair of backside bulk insulating films BBI, one of the pair of horizontal insulating portions BBH may extend in the first horizontal direction (the X direction) from a sidewall of the vertical insulating portion BBV toward a source/drain region 130 connected to the backside via contact MV and may contact the source/drain region 130 connected to the backside via contact MV.

A plurality of gate dielectric films 152 respectively surrounding the plurality of gate lines 160 may include a pair of gate dielectric films 152, which respectively surround a pair of gate lines 160 overlapping the pair of backside bulk insulating films BBI in the vertical direction (the Z direction). The vertical insulating portion BBV of each of the pair of backside bulk insulating films BBI may contact one gate dielectric film 152 adjacent thereto out of the pair of gate dielectric films 152.

As shown in FIG. 3A, the integrated circuit device 100 may include a plurality of semiconductor blocks SB and a plurality of semiconductor layers SL. Each of the plurality of semiconductor blocks SB may cover a sidewall of the backside via contact MV in the first horizontal direction (the X direction). Each of the plurality of semiconductor layers SL may be spaced apart from a semiconductor block SB in the vertical direction (the Z direction) with the horizontal insulating portion BBH of the backside bulk insulating film BBI therebetween. Some semiconductor layers SL from among the plurality of semiconductor layers SL may each be arranged between the horizontal insulating portion BBH of the backside bulk insulating film BBI and a gate line 160. The plurality of semiconductor blocks SB and the plurality of semiconductor layers SL may each include silicon (Si).

At least some semiconductor layers SL from among the plurality of semiconductor layers SL may each cover the sidewall of the vertical insulating portion BBV of the backside bulk insulating film BBI in the first horizontal direction (the X direction). Each of the plurality of semiconductor layers SL may be arranged between the horizontal insulating portion BBH and a portion of the gate dielectric film 152, such that the semiconductor layer covers a lowermost surface of the gate line 160. Herein, the lowermost surface of the gate line 160 may refer to a surface of the gate line 160 being closest the backside power rail MPR. The plurality of semiconductor layers SL may each be arranged between the gate dielectric film 152 and the horizontal insulating portion BBH of the backside bulk insulating film BBI to cover the sidewall of the vertical insulating portion BBV of the backside bulk insulating film BBI.

As shown in FIG. 3C, both sidewalls of at least one of the plurality of semiconductor blocks SB in the second horizontal direction (the Y direction) may be covered by a device isolation film 112. As shown in FIG. 3B, both sidewalls of a portion, which is adjacent to the gate line 160, of the backside bulk insulating film BBI in the second horizontal direction (the Y direction) may be covered by the device isolation film 112. At least one of the plurality of semiconductor blocks SB may have a surface contacting the source/drain region 130.

As shown in FIG. 3B, the device isolation film 112 may have a first surface 112A, which faces the gate line 160 with the gate dielectric film 152 therebetween, and a second surface 112B, which is on an opposite side to the first surface 112A in the vertical direction (the Z direction) and contacts the backside bulk insulating film BBI. In addition, as shown in FIG. 3C, the device isolation film 112 may include a third surface 112C facing the backside via contact MV in the second horizontal direction (the Y direction) and contacting the backside via contact MV, as well as a fourth surface 112D contacting the backside power rail MPR, and a fifth surface 112E facing the semiconductor block SB in the second horizontal direction (the Y direction) and contacting the semiconductor block SB. The device isolation film 112 may include an oxide film, a nitride film, or a combination thereof.

As shown in FIGS. 3A and 3B, a plurality of nanosheet stacks NSS may be respectively arranged over the plurality of backside bulk insulating films BBI. The plurality of nanosheet stacks NSS may be arranged to respectively overlap the plurality of backside bulk insulating films BBI in the vertical direction (the Z direction). Each of the plurality of nanosheet stacks NSS may include at least one nanosheet spaced apart from the backside bulk insulating film BBI in the vertical direction (the Z direction). As used herein, the term “nanosheet” may refer to a conductive structure having a cross-section that is substantially perpendicular to a current-flowing direction. The nanosheet may also be understood as including a nanowire. Although the figure illustrates a configuration in which one nanosheet stack NSS includes three nanosheets, that is, the first nanosheet N1, the second nanosheet N2, and the third nanosheet N3, embodiments are not limited thereto. The number of nanosheets in the nanosheet stack NSS may be variously selected as needed.

In one nanosheet stack NSS, the first nanosheet N1, the second nanosheet N2, and the third nanosheet N3 may be spaced apart from each other in the vertical direction (the Z direction). The first nanosheet N1, the second nanosheet N2, and the third nanosheet N3 may respectively have different vertical distances (Z-direction distances) from the backside bulk insulating film BBI below the first nanosheet N1, the second nanosheet N2, and the third nanosheet N3 in the vertical direction (the Z direction). Each of the first nanosheet N1, the second nanosheet N2, and the third nanosheet N3 of one nanosheet stack NSS may be surrounded by one gate line 160. Each of the first nanosheet N1, the second nanosheet N2, and the third nanosheet N3 of one nanosheet stack NSS may be used as a channel region of a nanosheet transistor TR (see FIG. 2). In one or more embodiments, each of the first nanosheet N1, the second nanosheet N2, and the third nanosheet N3 may include a Si layer, a SiGe layer, or a combination thereof. In one or more embodiments, the first nanosheet N1, the second nanosheet N2, and the third nanosheet N3 may include the same material.

In one or more embodiments, respective thicknesses of the first nanosheet N1, the second nanosheet N2, and the third nanosheet N3 in the vertical direction (the Z direction) may be equal to or substantially equal to each other. As shown in FIG. 4, in the vertical direction (the Z direction), a thickness T11 of each of the plurality of semiconductor layers SL may be greater than a thickness T12 of each of the first nanosheet N1, the second nanosheet N2, and the third nanosheet N3. In one or more embodiments, each of the first nanosheet N1, the second nanosheet N2, and the third nanosheet N3 may have a thickness in a range of about 4 nm to about 6 nm in the vertical direction (the Z direction). The thickness T11 of each of the plurality of semiconductor layers SL may be in a range of about 5 nm to about 20 nm such that the thickness T11 of each of the plurality of semiconductor layers SL is greater than the thickness T12 of each of the first nanosheet N1, the second nanosheet N2, and the third nanosheet N3. However, the thickness range of the semiconductor layers SL is not limited thereto.

As shown in FIGS. 3A and 3B, each of the plurality of gate lines 160 may be arranged over the backside bulk insulating film BBI to cover the plurality nanosheet stacks NSS and surround at least portions of the first nanosheet N1, the second nanosheet N2, and the third nanosheet N3. Each of the plurality of gate lines 160 may include a main gate portion 160M, which extends lengthwise in the second horizontal direction (Y direction) to cover an upper surface of the nanosheet stack NSS, and a plurality of sub-gate portions 160S, which are integrally connected to the main gate portion 160M and are respectively arranged in separation spaces between the first nanosheet N1, the second nanosheet N2, and the third nanosheet N3. In the vertical direction (Z direction), the thickness of each of the plurality of sub-gate portions 160S may be less than the thickness of the main gate portion 160M. Each of the plurality of gate lines 160 may extend to a space between the backside bulk insulating film BBI and the first nanosheet N1. The first nanosheet N1, the second nanosheet N2, and the third nanosheet N3 may have a GAA structure in which the first nanosheet N1, the second nanosheet N2, and the third nanosheet N3 are completely surrounded by the gate line 160.

Each of the plurality of gate lines 160 may include a metal, a metal nitride, a metal carbide, or a combination thereof. The metal may be at least one of Ti, W, Ru, Nb, Mo, Hf, Ni, Co, Pt, Yb, Tb, Dy, Er, and Pd. The metal nitride may be at least one of TiN and TaN. The metal carbide may include TiAIC. However, a material constituting each of the plurality of gate lines 160 is not limited to the examples set forth above.

The gate dielectric film 152 may be arranged between the nanosheet stack NSS and the gate line 160. The gate dielectric film 152 may include a stack structure of an interface dielectric film and a high-k film. The interface dielectric film may include a low-k material film having a dielectric constant of about 9 or less, such as a silicon oxide film, a silicon oxynitride film, or a combination thereof. In one or more embodiments, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

Each of the plurality of source/drain regions 130 may be arranged adjacent to at least one gate line 160 among the plurality of gate lines 160. Each of the plurality of source/drain regions 130 may have surfaces facing the first nanosheet N1, the second nanosheet N2, and the third nanosheet N3, which are included in the nanosheet stack NSS adjacent thereto.

Each of the plurality of source/drain regions 130 may include an epitaxially grown semiconductor layer. In one or more embodiments, each of the plurality of source/drain regions 130 may include an epitaxially grown Si layer, an epitaxially grown SiC layer, or a plurality of epitaxially grown SiGe layers. In one or more embodiments, when the source/drain region 130 constitutes an n-type metal-oxide-semiconductor (MOS) (NMOS) transistor, the source/drain region 130 may include a Si layer doped with an n-type dopant or a SiC layer doped with an n-type dopant. The n-type dopant may be at least one of phosphorus (P), arsenic (As), and antimony (Sb). When the source/drain region 130 constitutes a p-type MOS (PMOS) transistor, the source/drain region 130 may include a SiGe layer doped with a p-type dopant. The p-type dopant may be at least one of boron (B) and gallium (Ga). When the source/drain region 130 constitutes a PMOS transistor, the Ge content in the SiGe layer doped with the p-type dopant may increase with the decreasing distance from the outermost surface of the source/drain region 130 toward the center of the source/drain region 130. In one or more embodiments, when the source/drain region 130 constitutes a PMOS transistor, the source/drain region 130 may include a first buffer layer, a second buffer layer, and a main body layer stacked in the stated order from the outermost surface thereof toward the center thereof. The first buffer layer may form the outermost surface of the source/drain region 130. The Ge content in the second buffer layer may be greater than the Ge content in the first buffer layer, and the Ge content in the main body layer may be greater than the Ge content in the second buffer layer. That is, when the source/drain region 130 constitutes a PMOS transistor, the source/drain region 130 may include a SiGe layer doped with a p-type dopant, and an outermost portion of the SiGe layer constituting the source/drain region 130 may have the lowest Ge content. For example, the first buffer layer may include a Si₁₋ₓGeₓ layer (where 0.0<x≤0.15) doped with boron (B), the second buffer layer may include a Si₁₋ₓGeₓ layer (where 0.15≤x≤0.20) doped with boron (B), and the main body layer may include a Si₁₋ₓGeₓ layer (where 0.20<x<<0.70) doped with boron (B). That is, the Ge content in the first buffer layer may be more than about 0 at % but not more than about 15 at %, the Ge content in the second buffer layer may be about 15 at % to about 20 at %, and the Ge content in the main body layer may be about 20 at % to about 70 at %, but embodiments are not limited thereto.

Either sidewall of each of the plurality of sub-gate portions 160S, which are included in each of the plurality of gate lines 160, may be spaced apart from the source/drain region 130 with the gate dielectric film 152 therebetween. The gate dielectric film 152 may include portions arranged between the sub-gate portion 160S of the gate line 160 and each of the first nanosheet N1, the second nanosheet N2, and the third nanosheet N3, portions arranged between the sub-gate portion 160S of the gate line 160 and the source/drain region 130, and a portion arranged between the sub-gate portion 160S closest to the backside bulk insulating film BBI, among the plurality of sub-gate portions 160S of the gate line 160, and the backside bulk insulating film BBI. The backside bulk insulating film BBI may include portions contacting the gate dielectric film 152.

As shown in FIG. 4, in the vertical direction (the Z direction), a thickness T13 of the horizontal insulating portion BBH of each of the plurality of backside bulk insulating films BBI may be greater than a thickness T14 of each of the plurality of sub-gate portions 160S. The thickness T13 of the horizontal insulating portion BBH of each of the plurality of backside bulk insulating films BBI may be equal to or substantially equal to a distance T15 between the first nanosheet N1 and the uppermost surface of the vertical insulating portion BBV of the backside bulk insulating film BBI which is closes to the first nanosheet N1.

In the integrated circuit device 100, the plurality of source/drain regions 130 may include a pair of source/drain regions 130 that are adjacent to each other in the first horizontal direction (the X direction) with one nanosheet stack NSS therebetween. The gate line 160 may be arranged between the pair of source/drain regions 130 to extend lengthwise in the second horizontal direction (the Y direction) while surrounding the first nanosheet N1, the second nanosheet N2, and the third nanosheet N3. The backside via contact MV may be configured to be connected to one source/drain region 130 among the pair of source/drain regions 130. According to one or more embodiments, the integrated circuit device 100 may further include another backside via contact MV configured to be connected to one source/drain region 130 among the pair of source/drain regions 130.

A metal silicide film 198 may be arranged between the source/drain region 130 and the backside via contact MV. The metal silicide film 198 may contact a surface of the source/drain region 130 that faces the backside power rail MPR. The backside via contact MV may contact the metal silicide film 198. The backside via contact MV may be configured to be connected to the source/drain region 130 via the metal silicide film 198. The backside via contact MV may pass through a portion of the source/drain region 130 in the vertical direction (the Z direction).

In one or more embodiments, the metal silicide film 198 may include Ti, W, Ru, Nb, Mo, Hf, Ni, Co, Pt, Yb, Tb, Dy, Er, or Pd. For example, the metal silicide film 198 may include titanium silicide.

One backside bulk insulating film BBI may be arranged between the pair of source/drain regions 130, and the one backside bulk insulating film BBI may be spaced apart from the gate line 160 in the vertical direction (the Z direction) with the gate dielectric film 152 therebetween. In the one backside bulk insulating film BBI, the vertical insulating portion BBV may be located below the gate line 160 in the vertical direction (the Z direction) and may extend lengthwise in the vertical direction (the Z direction). One sidewall of the vertical insulating portion BBV in the first horizontal direction (the X direction) may include a portion facing the backside via contact MV. The one backside bulk insulating film BBI may include a pair of horizontal insulating portions BBH protruding from both sidewalls of the vertical insulating portion BBV in the first horizontal direction (the X direction). Each of the pair of horizontal insulating portions BBH may contact one source/drain region 130 adjacent thereto out of a pair of source/drain regions 130 that are adjacent to each other with a backside bulk insulating film BBI therebetween.

As shown in FIG. 3A, the width of the vertical insulating portion BBV of the backside bulk insulating film BBI in the first horizontal direction (the X direction) may gradually increase toward the backside power rail MPR and away from the gate line 160. In the first horizontal direction (the X direction), a maximum width WX of the vertical insulating portion BBV of the backside bulk insulating film BBI may be less than the maximum width of each of the first nanosheet N1, the second nanosheet N2, and the third nanosheet N3. In the first horizontal direction (the X direction), both sidewalls of the vertical insulating portion BBV of the backside bulk insulating film BBI may each contact the backside power rail MPR.

As shown in FIG. 3A, both sidewalls of the backside via contact MV in the first horizontal direction (the X direction), among sidewalls of the backside via contact MV, may be covered by the semiconductor block SB. Herein, the sidewall covered by the semiconductor block SB, among the sidewalls of the backside via contact MV, may be referred to as a first sidewall. As shown in FIG. 3C, both sidewalls of the backside via contact MV in the second horizontal direction (the Y direction), among the sidewalls of the backside via contact MV, may be covered by the device isolation film 112. Herein, the sidewall covered by the device isolation film 112, among the sidewalls of the backside via contact MV, may be referred to as a second sidewall.

The plurality of gate lines 160, the plurality of nanosheet stacks NSS, and the plurality of source/drain regions 130 may constitute a plurality of nanosheet transistors TR. Each of the plurality of nanosheet transistors TR may include an NMOS transistor, a PMOS transistor, or a combination thereof.

As shown in FIG. 3A, both sidewalls of the gate line 160 may be respectively covered by a plurality of main insulating spacers 118. Each of the plurality of main insulating spacers 118 may be arranged on the upper surface of the nanosheet stack NSS to cover a sidewall of the main gate portion 160M. Each of the plurality of main insulating spacers 118 may be apart from the gate line 160 with the gate dielectric film 152 therebetween.

As shown in FIG. 3C, a plurality of side insulating spacers 119 may be arranged on the device isolation film 112. At least a portion of each of the plurality of side insulating spacers 119 may cover a sidewall of the source/drain region 130. In one or more embodiments, each of the plurality of side insulating spacers 119 may be integrally connected to a main insulating spacer 118 adjacent thereto.

Each of the plurality of main insulating spacers 118 and the plurality of side insulating spacers 119 may include silicon nitride, silicon oxide, SiOC, SiOCN, SiCN, SiBN, SION, SiBCN, SiOF, SiOCH, or a combination thereof. Each of the plurality of main insulating spacers 118 and the plurality of side insulating spacers 119 may include a single film including one material film among the materials listed above or may include a multi-film including a plurality of material films among the materials listed above.

As shown in FIGS. 3A and 3B, the upper surface of each of the gate line 160, the gate dielectric film 152, and the main insulating spacer 118 may be covered by a capping insulating pattern 168. Each capping insulating pattern 168 may include a silicon nitride film.

The plurality of source/drain regions 130, the device isolation film 112, the plurality of main insulating spacers 118, and the plurality of side insulating spacers 119 may be covered by an insulating liner 142. An inter-gate dielectric 144 may be arranged on the insulating liner 142. The inter-gate dielectric 144 may be arranged between a pair of gate lines 160, which are adjacent to each other in the first horizontal direction (the X direction), and between a pair of source/drain regions 130 adjacent to each other. In one or more embodiments, the insulating liner 142 may include, but is not limited to, silicon nitride, SiCN, SiBN, SION, SiOCN, SiBCN, or a combination thereof. The inter-gate dielectric 144 may include, but is not limited to, a silicon oxide film.

As shown in FIGS. 3A and 3C, a plurality of source/drain contacts CA may be arranged respectively on the plurality of source/drain regions 130 between a pair of gate lines 160 adjacent to each other from among the plurality of gate lines 160. Each of the plurality of source/drain contacts CA may be configured to be electrically connected to at least one source/drain region 130 among the plurality of source/drain regions 130. For example, as shown in FIG. 2, one source/drain contact CA may be connected to two adjacent source/drain regions 130, or as shown in FIGS. 2 and 3C, one source/drain contact CA may be connected to one source/drain region 130, but embodiments are not limited thereto. The source/drain contact CA may be apart from the main gate portion 160M of the gate line 160, which is adjacent thereto, in the first horizontal direction (X direction) with the main insulating spacer 118 therebetween.

A metal silicide film 172 may be arranged between the source/drain region 130 and the source/drain contact CA. The metal silicide film 172 may contact the source/drain region 130. The source/drain contact CA may pass through the inter-gate dielectric 144 and the insulating liner 142 in the vertical direction (the Z direction) to contact the metal silicide film 172. The source/drain contact CA may be configured to be connected to the source/drain region 130 via the metal silicide film 172. The source/drain contact CA may pass through a portion of the source/drain region 130 in the vertical direction (Z direction). The insulating liner 142 and the inter-gate dielectric 144 may surround a sidewall of the source/drain contact CA. A constituent material of the metal silicide film 172 may be the same as described as to that of the metal silicide film 198. In one or more embodiments, the source/drain contact CA may include only a metal plug including a single metal. In one or more embodiments, the source/drain contact CA may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof. The conductive barrier film may include a metal or a conductive metal nitride. For example, the conductive barrier film may include, but is not limited to, Ti, Ta, W, TiN, TaN, WN, WCN, TiSiN, TaSIN, WSiN, or a combination thereof.

Respective upper surfaces of the source/drain contact CA, a plurality of capping insulating patterns 168, and the inter-gate dielectric 144 may be covered by an upper insulating structure 180. The upper insulating structure 180 may include a frontside etch stop film 182 and an upper insulating film 184, which are sequentially on each of the plurality of source/drain contacts CA, the plurality of capping insulating patterns 168, and the inter-gate dielectric 144. The frontside etch stop film 182 may include silicon carbide (SIC), SiN, SiCN, SiOC, AlN, AION, AIO, AlOC, or a combination thereof. The upper insulating film 184 may include an oxide film, a nitride film, an ultra-low k (ULK) film having an ultra-low dielectric constant of about 2.2 to about 2.4, or a combination thereof. For example, the upper insulating film 184 may include, but is not limited to, a tetraethylorthosilicate (TEOS) film, a high-density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof.

A source/drain via contact VA may be arranged on the source/drain contact CA. A plurality of source/drain via contacts VA may each pass through the upper insulating structure 180 to contact the source/drain contact CA. The source/drain region 130 connected to the source/drain contact CA, among the plurality of source/drain regions 130, may be configured to be electrically connected to the source/drain via contact VA via the metal silicide film 172 and the source/drain contact CA. Each of the plurality of source/drain via contacts VA may include, but is not limited to, molybdenum (Mo) or tungsten (W).

As shown in FIG. 3B, a gate contact CB may be arranged on the gate line 160. The gate contact CB may be configured to pass through the upper insulating structure 180 and the capping insulating pattern 168 in the vertical direction (Z direction) to be connected to the gate line 160. A lower surface of the gate contact CB may contact the upper surface of the gate line 160. The gate contact CB may include a contact plug including molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not limited to the examples set forth above. In one or more embodiments, the gate contact CB may further include a conductive barrier pattern surrounding a portion of the contact plug. The conductive barrier pattern of the gate contact CB may include a metal or a metal nitride. For example, the conductive barrier pattern may include, but is not limited to, Ti, Ta, W, TiN, TaN, WN, WCN, TiSiN, TaSIN, WSiN, or a combination thereof.

An upper surface of the upper insulating structure 180 may be covered by a frontside interlayer dielectric 186. A constituent material of the frontside interlayer dielectric 186 may be substantially the same as the constituent material of the upper insulating film 184 described above. A plurality of upper wiring layers M1 may be arranged through the frontside interlayer dielectric 186. Each of the plurality of upper wiring layers M1 may be connected to the source/drain via contact VA or the gate contact CB. Each of the plurality of upper wiring layers M1 may include, but is not limited to, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof.

As described with reference to FIGS. 2, 3A to 3C, and 4, the integrated circuit device 100 may include a plurality of backside bulk insulating films BBI, and the plurality of backside bulk insulating films BBI may include a pair of backside bulk insulating films BBI arranged on both sides of one backside via contact MV with the one backside via contact MV therebetween. Each of the plurality of backside bulk insulating films BBI may include a vertical insulating portion BBV, which is located below the gate line 160 in the vertical direction (the Z direction) and extends lengthwise in the vertical direction (the Z direction), and a horizontal insulating portion BBH, which protrudes in the first horizontal direction (the X direction) from the sidewall of the vertical insulating portion BBV and contacts the source/drain region 130. According to the integrated circuit device 100, even when a plurality of wiring structures are included at a relatively high density in an area reduced due to down-scaling, the generation of unintended leakage current between the backside via contact MV and conductive regions therearound may be prevented by the backside bulk insulating film BBI. In addition, in the backside bulk insulating film BBI, a portion adjacent to the lowermost surface of the gate line 160 may be spaced apart from the gate line 160 with the gate dielectric film 152 therebetween. Because the backside bulk insulating film BBI is formed to include the horizontal insulating portion BBH, even when a portion of the gate dielectric film 152, which covers the lowermost surface of the gate line 160, is temporarily exposed while processes for forming the backside bulk insulating film BBI are being performed, there may be little to no concern of damage to the exposed gate dielectric film 152 due to a process atmosphere, and other components around the backside bulk insulating film BBI may be prevented from deteriorating during a fabrication process of the integrated circuit device 100 including the backside bulk insulating film BBI. Therefore, the integrated circuit device 100 according to one or more embodiments may provide a stable and optimized wiring structure, even in an area reduced due to down-scaling, and thus, the degree of integration and the reliability of the integrated circuit device 100 may improve.

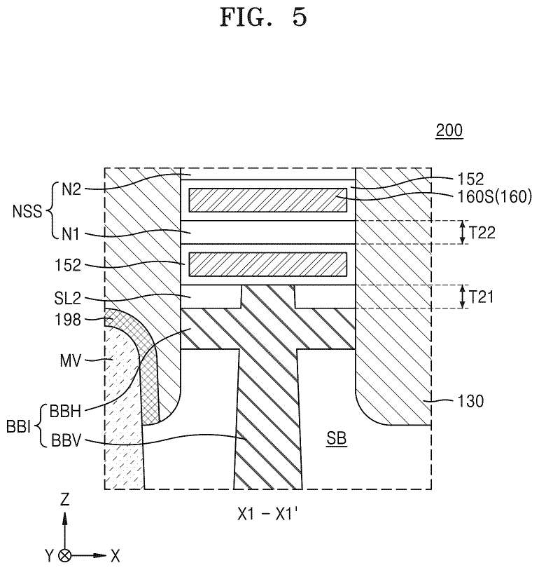

FIGS. 5 to 8 are cross-sectional views respectively illustrating integrated circuit devices 200, 300, 400, and 500 according to one or more embodiments. FIGS. 5 to 8 respectively illustrate enlarged cross-sectional configurations of portions of the integrated circuit devices 200, 300, 400, and 500, each of the portions corresponding to a region EX1 of FIG. 3A. In FIGS. 5 to 8, the same reference numerals as in FIGS. 2, 3A to 3C, and 4 respectively denote the same members, and here, repeated descriptions thereof are omitted. Components shown in FIGS. 5 to 8 may constitute a portion of the plurality of cells LC shown in FIG. 1.

Referring to FIG. 5, the integrated circuit device 200 may have substantially the same configuration as the integrated circuit device 100 described with reference to FIGS. 2, 3A to 3C, and 4. However, the integrated circuit device 200 may include a plurality of semiconductor layers SL2.

The plurality of semiconductor layers SL2 may have substantially the same configuration as the plurality of semiconductor layers SL described with reference to FIGS. 3A and 4. However, in the vertical direction (the Z direction), a thickness T21 of each of the plurality of semiconductor layers SL2 may be equal to or substantially equal to a thickness T22 of each of the first nanosheet N1, the second nanosheet N2, and the third nanosheet N3.

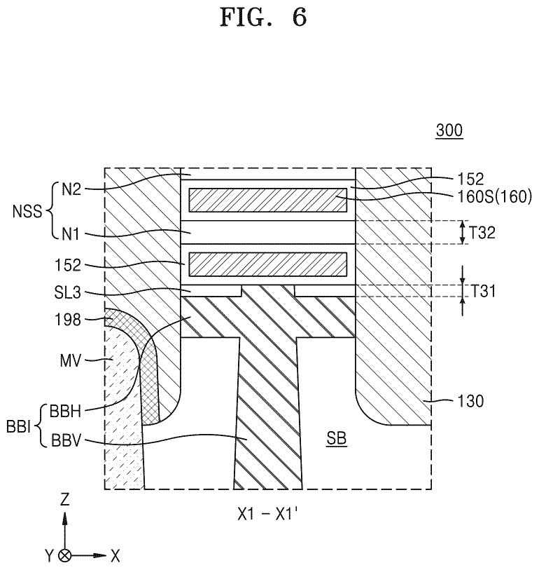

Referring to FIG. 6, the integrated circuit device 300 may have substantially the same configuration as the integrated circuit device 100 described with reference to FIGS. 2, 3A to 3C, and 4. However, the integrated circuit device 300 may include a plurality of semiconductor layers SL3.

The plurality of semiconductor layers SL3 may have substantially the same configuration as the plurality of semiconductor layers SL described with reference to FIGS. 3A and 4. However, in the vertical direction (the Z direction), a thickness T31 of each of the plurality of semiconductor layers SL3 may be equal to or substantially equal to a thickness T32 of each of the first nanosheet N1, the second nanosheet N2, and the third nanosheet N3.

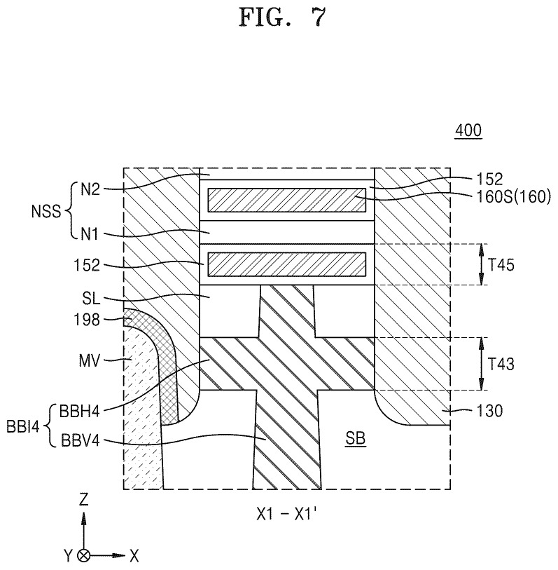

Referring to FIG. 7, the integrated circuit device 400 may have substantially the same configuration as the integrated circuit device 100 described with reference to FIGS. 2, 3A to 3C, and 4. However, the integrated circuit device 400 may include a backside bulk insulating film BBI4 instead of the backside bulk insulating film BBI of the integrated circuit device 100. Each backside bulk insulating film BBI4 may include a vertical insulating portion BBV4 and a pair of horizontal insulating portions BBH4 respectively protruding from both sidewalls of the vertical insulating portion BBV4 in the first horizontal direction (the X direction).

The backside bulk insulating film BBI4 and both the vertical insulating portion BBV4 and the horizontal insulating portion BBH4 of the backside bulk insulating film BBI4 may be substantially the same as described with reference to FIGS. 2, 3A to 3C, and 4 regarding the backside bulk insulating film BBI and both the vertical insulating portion BBV and the horizontal insulating portion BBH of the backside bulk insulating film BBI, respectively. However, in the vertical direction (the Z direction), a thickness T43 of the horizontal insulating portion BBH4 of the backside bulk insulating film BBI4 may be greater than a minimum distance T45 between the first nanosheet N1 and the uppermost surface, which is closest to the first nanosheet N1, of the vertical insulating portion BBV4 of the backside bulk insulating film BBI4.

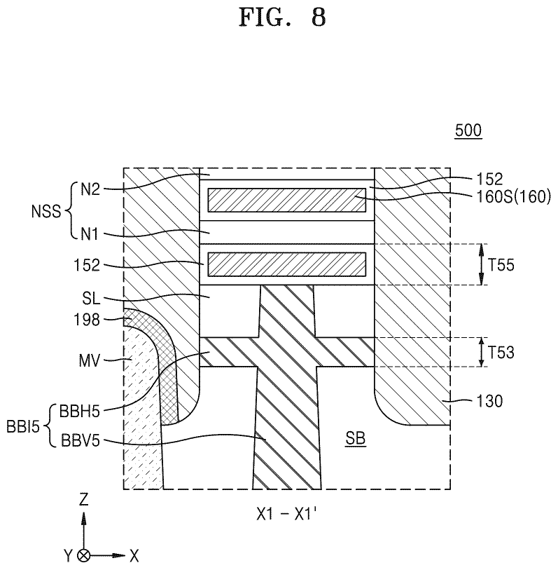

Referring to FIG. 8, the integrated circuit device 500 may have substantially the same configuration as the integrated circuit device 100 described with reference to FIGS. 2, 3A to 3C, and 4. However, the integrated circuit device 500 may include a backside bulk insulating film BBI5 instead of the backside bulk insulating film BBI of the integrated circuit device 100. Each backside bulk insulating film BBI5 may include a vertical insulating portion BBV5 and a pair of horizontal insulating portions BBH5 respectively protruding from both sidewalls of the vertical insulating portion BBV5 in the first horizontal direction (the X direction).

The backside bulk insulating film BBI5 and both the vertical insulating portion BBV5 and the horizontal insulating portion BBH5 of the backside bulk insulating film BBI5 may be substantially the same as described with reference to FIGS. 2, 3A to 3C, and 4 regarding the backside bulk insulating film BBI and both the vertical insulating portion BBV and the horizontal insulating portion BBH of the backside bulk insulating film BBI, respectively. However, in the vertical direction (the Z direction), a thickness T53 of the horizontal insulating portion BBH5 of the backside bulk insulating film BBI5 may be less than a minimum distance T55 between the first nanosheet N1 and the uppermost surface, which is closest to the first nanosheet N1, of the vertical insulating portion BBV5 of the backside bulk insulating film BBI5.

Similar to the integrated circuit device 100 described with reference to FIGS. 2, 3A to 3C, and 4, each of the integrated circuit devices 200, 300, 400, and 500 may include the backside bulk insulating film BBI, BBI4, or BBI5. Each of the backside bulk insulating films BBI, BBI4, and BBI5 may be arranged adjacent to the backside via contact MV in the first horizontal direction (the X direction) to enhance insulation between the backside via contact MV and conductive regions around the backside via contact MV, and to suppress leakage current therebetween. According to each of the integrated circuit devices 200, 300, 400, and 500, even when a plurality of wiring structures are included at a relatively high density in an area reduced due to down-scaling, the generation of unintended leakage current between the backside via contact MV and conductive regions therearound may be prevented by the backside bulk insulating film BBI, BBI4, or BBI5. In addition, in each of the backside bulk insulating films BBI, BBI4, and BBI5, a portion adjacent to the lowermost surface of the gate line 160 may be spaced apart from the gate line 160 with the gate dielectric film 152 therebetween. Because the backside bulk insulating films BBI, BBI4, and BBI5 may be formed to respectively include the horizontal insulating portions BBH, BBH4, and BBH5, even when a portion of the gate dielectric film 152, which covers the lowermost surface of the gate line 160, is temporarily exposed while processes for forming each of the backside bulk insulating films BBI, BBI4, and BBI5 are being performed, there is little to no concern of damage to the exposed gate dielectric film 152 due to a process atmosphere, and other components around each of the backside bulk insulating films BBI, BBI4, and BBI5 may be prevented from deteriorating during a fabrication process of each of the integrated circuit devices 200, 300, 400, and 500 including the backside bulk insulating film BBI, BBI4, or BBI5. Therefore, each of the integrated circuit devices 200, 300, 400, and 500 according to one or more embodiments may provide a stable and optimized wiring structure, even in an area reduced due to down-scaling, and thus, the degree of integration and the reliability of each of the integrated circuit devices 200, 300, 400, and 500 may improve.

Next, a method of fabricating an integrated circuit device, according to one or more embodiments, is described in detail.

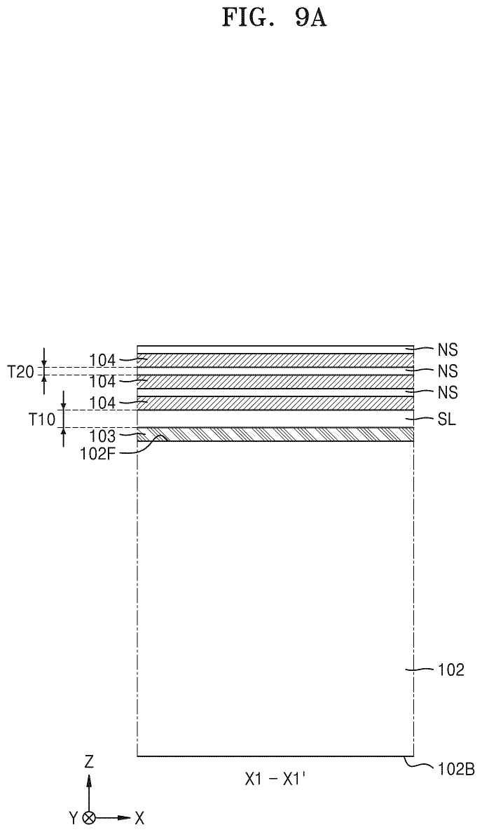

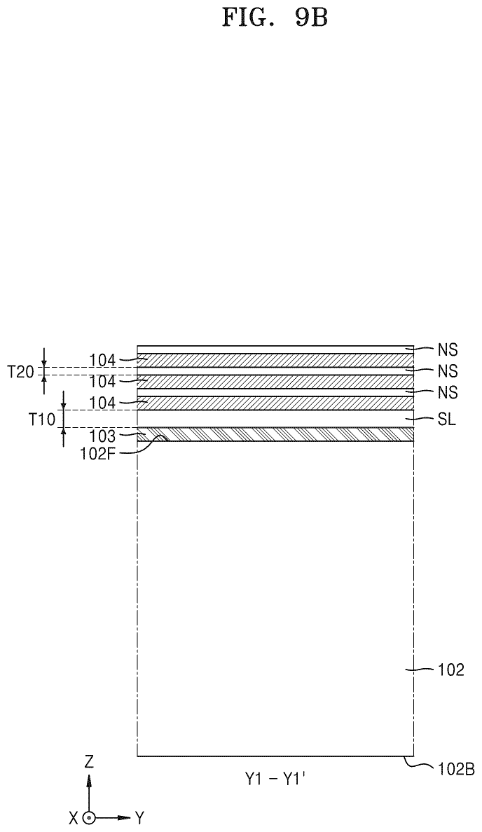

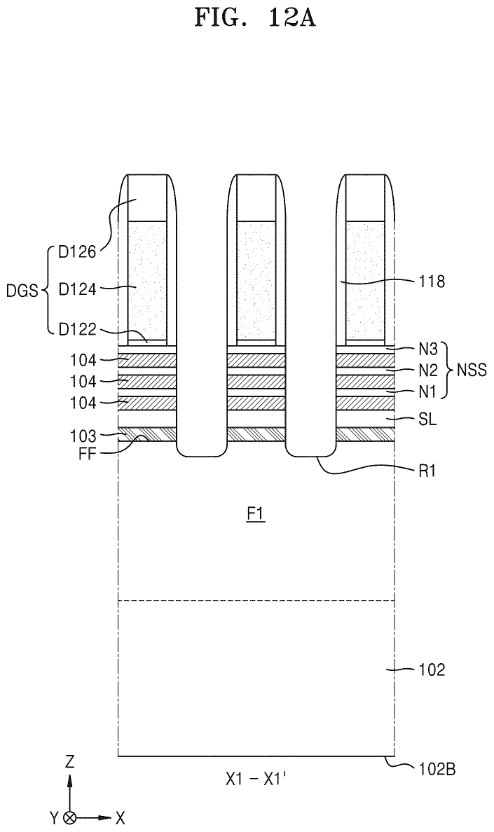

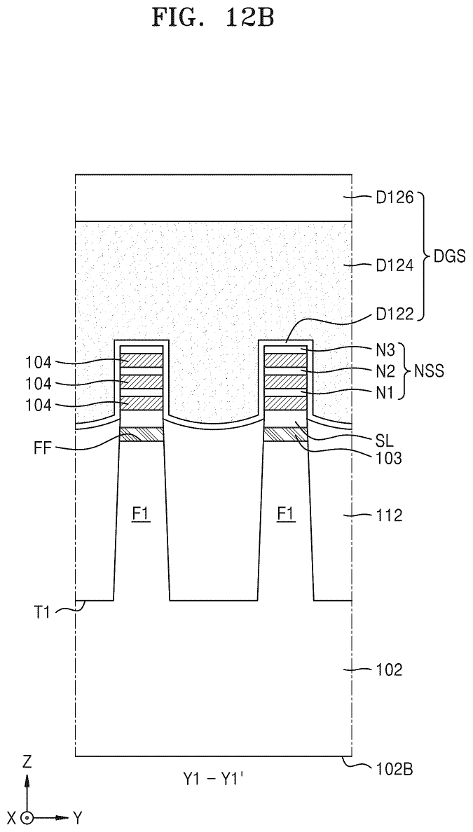

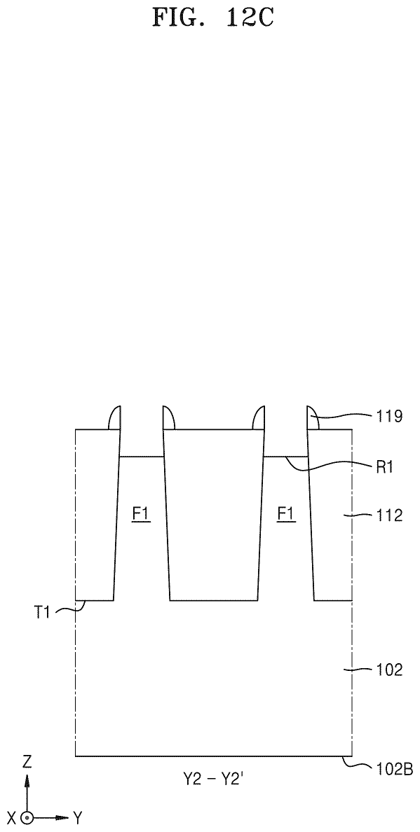

FIGS. 9A to 26B are diagrams respectively illustrating a method of fabricating an integrated circuit device, according to one or more embodiments. More specifically, FIGS. 9A, 10A, 11A, 12A, 13A, 14A, 15A, 16A, 17A, 18A, 19A, 20A, 21A, 22A, 23, 24A, 25A, and 26A are cross-sectional views respectively illustrating cross-sectional structures of a region corresponding to the cross-section taken along the line X1-X1′ of FIG. 2, according to the sequence of processes. FIGS. 9B, 10B, 11B, 12B, 13B, 14B, 15B, 16B, 17B, 18B, 19B, 20B, 21B, and 22B are cross-sectional views respectively illustrating cross-sectional structures of a region corresponding to the cross-section taken along the line Y1-Y1′ of FIG. 2, according to the sequence of processes. FIGS. 12C, 13C, 16C, 17C, 18C, 24B, 25B, and 26B are cross-sectional views respectively illustrating cross-sectional structures of a region corresponding to the cross-section taken along the line Y2-Y2′ of FIG. 2.

An example of a method of fabricating the integrated circuit device 100 described with reference to FIGS. 2, 3A to 3C, and 4 is described with reference to FIGS. 9A to 26B. In FIGS. 9A to 26B, the same reference numerals as in FIGS. 2, 3A to 3C, and 4 respectively denote the same members, and here, repeated descriptions thereof may be omitted.

Referring to FIGS. 9A and 9B, a substrate 102 having a frontside surface 102F and a backside surface 102B, which are opposite to each other, may be prepared, and a blocking sacrificial semiconductor layer 103 and a semiconductor layer SL may be formed on or over the frontside surface 102F of the substrate 102. Next, a stack structure, in which a plurality of sacrificial semiconductor layers 104 and a plurality of nanosheet semiconductor layers NS are alternately stacked, may be formed on the semiconductor layer SL.

In the stack structure, the blocking sacrificial semiconductor layer 103 and the plurality of sacrificial semiconductor layers 104 may include the same material, and the semiconductor layer SL and the plurality of nanosheet semiconductor layers NS may include the same material. A material constituting the blocking sacrificial semiconductor layer 103 and the plurality of sacrificial semiconductor layers 104 and a material constituting the semiconductor layer SL and the plurality of nanosheet semiconductor layers NS may respectively include semiconductor materials having different etch selectivities. In one or more embodiments, each of the semiconductor layer SL and the plurality of nanosheet semiconductor layers NS may include a Si layer, and each of the blocking sacrificial semiconductor layer 103 and the plurality of sacrificial semiconductor layers 104 may include a SiGe layer. The SiGe layer constituting each of the blocking sacrificial semiconductor layer 103 and the plurality of sacrificial semiconductor layers 104 may have a constant Ge content in a range of about 10 at % to about 40 at %. In one or more embodiments, each of the blocking sacrificial semiconductor layer 103 and the plurality of sacrificial semiconductor layers 104 may include a SiGe layer, and the respective Ge contents in the blocking sacrificial semiconductor layer 103 and the plurality of sacrificial semiconductor layers 104 may be equal to or substantially equal to each other. In one or more embodiments, each of the blocking sacrificial semiconductor layer 103 and the plurality of sacrificial semiconductor layers 104 may include a SiGe layer, and the Ge content in the blocking sacrificial semiconductor layer 103 may be different from the Ge content in the plurality of sacrificial semiconductor layers 104. For example, the Ge content in the blocking sacrificial semiconductor layer 103 may be greater than the Ge content in the plurality of sacrificial semiconductor layers 104, but embodiments are not limited thereto.

In the vertical direction (the Z direction), a thickness T10 of the semiconductor layer SL may be greater than a thickness T20 of each of the plurality of nanosheet semiconductor layers NS.

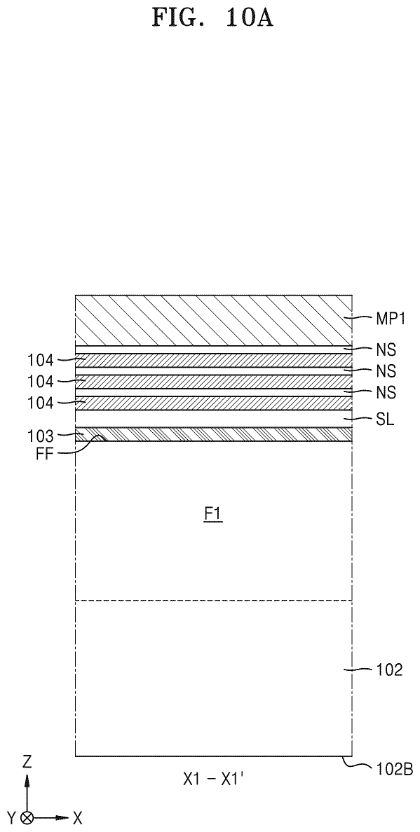

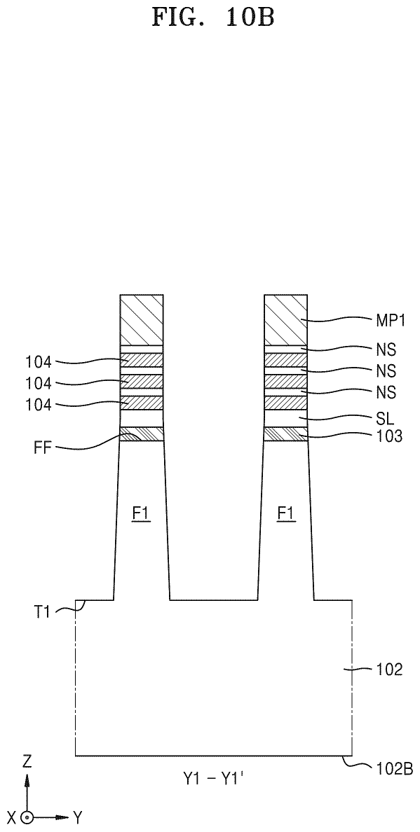

Referring to FIGS. 10A and 10B, a mask pattern MP1 having openings, which expose the upper surface of the stack structure, may be formed on the resulting product of FIGS. 9A and 9B. The mask pattern MP1 may include a stack structure of a silicon oxide film pattern and a silicon nitride film pattern. The mask pattern MP1 may include portions extending parallel to each other in the first horizontal direction (the X direction) over the substrate 102.

Each of the plurality of nanosheet semiconductor layers NS, the plurality of sacrificial semiconductor layers 104, the semiconductor layer SL, the blocking sacrificial semiconductor layer 103, and the substrate 102 may be partially etched by using the mask pattern MP1 as an etch mask. As a result, a plurality of fin-type active regions F1 may be formed in the substrate 102. A plurality of trench regions T1 may be defined on the substrate 102 by the plurality of fin-type active regions F1. A portion of each of the blocking sacrificial semiconductor layer 103, the semiconductor layer SL, the plurality of sacrificial semiconductor layers 104, and the plurality of nanosheet semiconductor layers NS may remain on or over a fin top surface FF of each of the plurality of fin-type active regions F1. The blocking sacrificial semiconductor layer 103 may contact the fin top surface FF of each of the plurality of fin-type active regions F1.

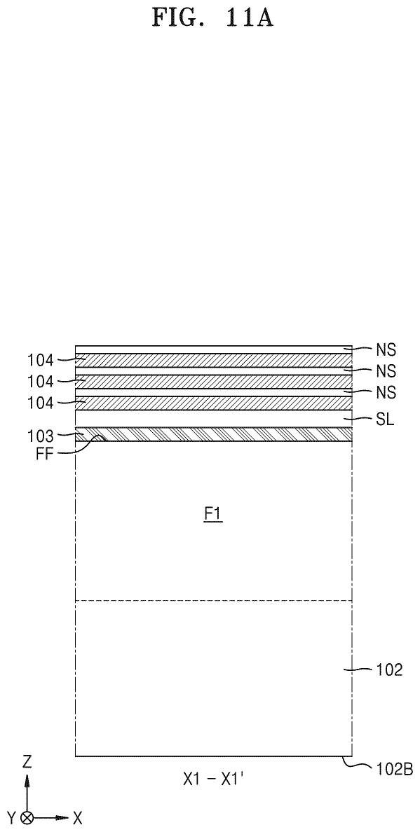

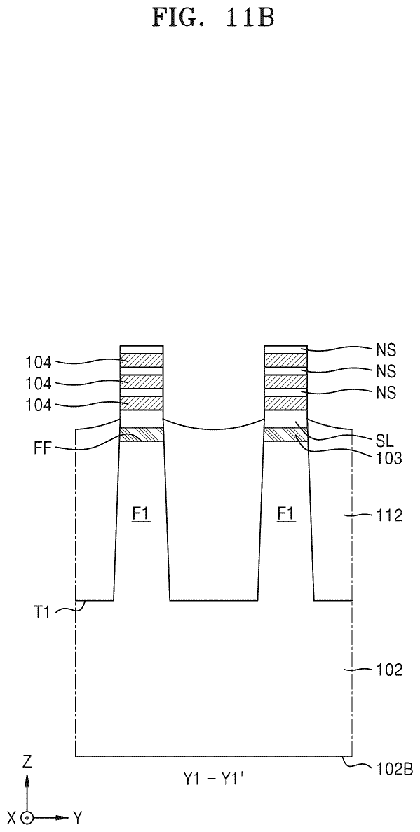

Referring to FIGS. 11A and 11B, the device isolation film 112 may be formed on the resulting product of FIGS. 10A and 10B. The device isolation film 112 may be formed to fill the plurality of trench regions T1 and cover sidewalls of each of the plurality of fin-type active regions F1 and sidewalls of the blocking sacrificial semiconductor layer 103.

To form the device isolation film 112, an insulating film may be formed on the resulting product of FIGS. 10A and 10B to have a thickness sufficient to fill the plurality of trench regions T1, and the upper surface of the mask pattern MP1 may be exposed by planarizing the obtained resulting product. Next, the mask pattern MP1 that is exposed may be removed, and then, a recess process for removing a portion of the insulating film may be performed. As a result, the device isolation film 112, which includes the remaining portion of the insulating film, may be formed. After the device isolation film 112 is formed, the stack structure including the plurality of sacrificial semiconductor layers 104 and the plurality of nanosheet semiconductor layers NS, which remain on or over the substrate 102, may protrude upward from the upper surface of the device isolation film 112, and the upper surface of the uppermost nanosheet semiconductor layer NS from among the plurality of nanosheet semiconductor layers NS may be exposed.

Referring to FIGS. 12A, 12B, and 12C, a plurality of dummy gate structures DGS may be formed on the resulting product of FIGS. 11A and 11B. Each of the plurality of dummy gate structures DGS may be formed to extend lengthwise in the second horizontal direction (the Y direction). Each of the plurality of dummy gate structures DGS may include a dummy oxide film D122, a dummy gate layer D124, and a capping layer D126, which may be stacked on the stack structure including the plurality of sacrificial semiconductor layers 104 and the plurality of nanosheet semiconductor layers NS. In one or more embodiments, the dummy gate layer D124 may include polysilicon and the capping layer D126 may include a silicon nitride film.

As shown in FIG. 12A, a plurality of insulating spacers 118 may be formed to respectively cover both sidewalls of each of the plurality of dummy gate structures DGS, and a portion of each of the plurality of sacrificial semiconductor layers 104 and the plurality of nanosheet semiconductor layers NS, a portion of the semiconductor layer SL and the blocking sacrificial semiconductor layer 103, and a portion of the fin-type active region F1 may be etched by using the plurality of dummy gate structures DGS and the plurality of insulating spacers 118 as an etch mask. As a result, the plurality of nanosheet semiconductor layers NS may be divided into the plurality of nanosheet stacks NSS, which each include the first to third nanosheets N1, N2, and N3, and each of the semiconductor layers SL and the blocking sacrificial semiconductor layer 103 may be divided into a plurality of pieces in the first horizontal direction (the X direction), whereby a plurality of recesses R1 may be defined in an upper portion of the fin-type active region F1. The width of each of the first to third nanosheets N1, N2, and N3 in the first horizontal direction (the X direction) may be defined by the plurality of recesses R1.

To form the plurality of recesses R1, the etching may be performed by dry etching, wet etching, or a combination thereof. During the formation of the plurality of insulating spacers 118 and the plurality of recesses R1, the plurality of side insulating spacers 119 may be formed as shown in FIG. 12C, the plurality of side insulating spacers 119 being arranged on the device isolation film 112 on both sides of each fin-type active region F1 in the second horizontal direction (the Y direction) to be respectively adjacent to the plurality of recesses R1.

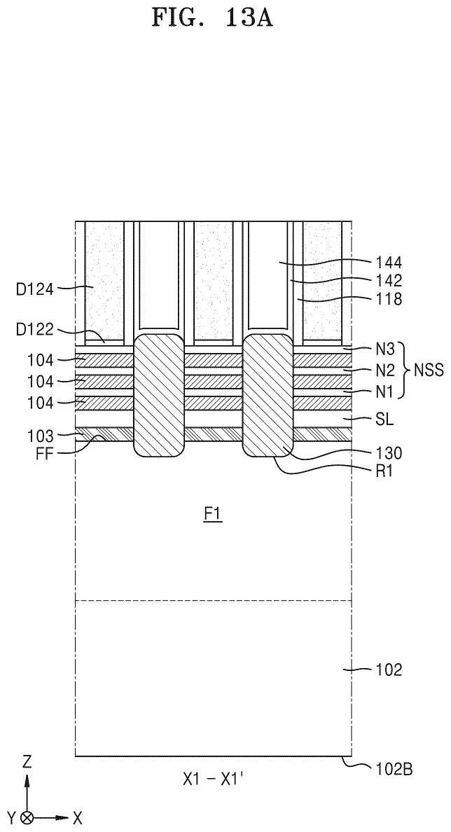

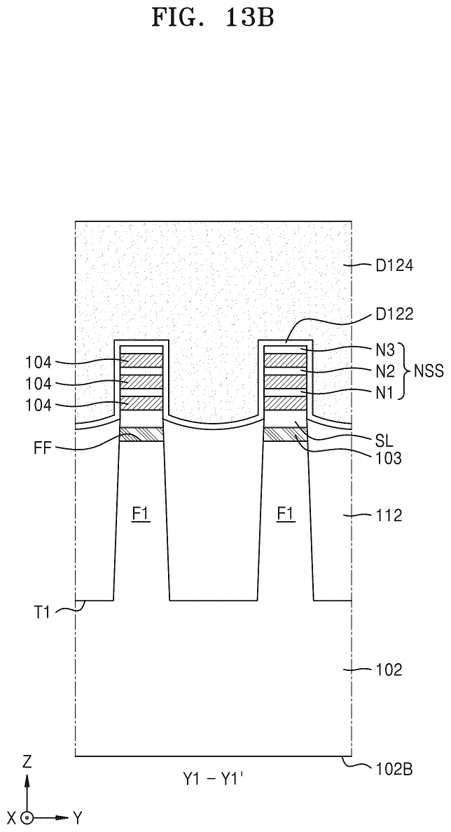

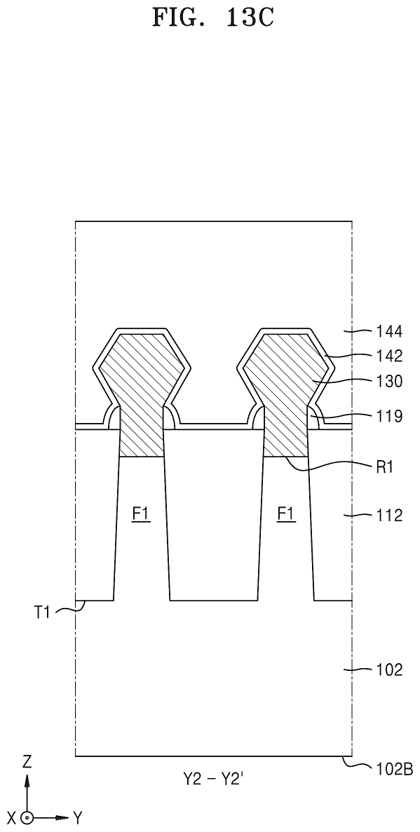

Referring to FIGS. 13A, 13B, and 13C, in the resulting product of FIGS. 12A, 12B, and 12C, a plurality of source/drain regions 130 may be formed to respectively fill the plurality of recesses R1. To form the plurality of source/drain regions 130, a semiconductor material may be epitaxially grown on the sidewall of each of the semiconductor layer SL, the blocking sacrificial semiconductor layer 103, and the first to third nanosheets N1, N2, and N3 and the surface of the fin-type active region F1, which are exposed in each of the plurality of recesses R1.

Next, the insulating liner 142 may be formed to cover a resulting product in which the plurality of source/drain regions 130 are formed, followed by forming the inter-gate dielectric 144 on the insulating liner 142, and then, each of the insulating liner 142 and the inter-gate dielectric 144 may be partially etched, thereby exposing upper surfaces of a plurality of capping layers D126 (see FIGS. 12A and 12B). Next, the dummy gate layer D124 may be exposed by removing the plurality of capping layers D126, and each of the insulating liner 142 and the inter-gate dielectric 144 may be partially removed such that the upper surface of the inter-gate dielectric 144 and the upper surface of the dummy gate layer D124 are at an approximately equal level.

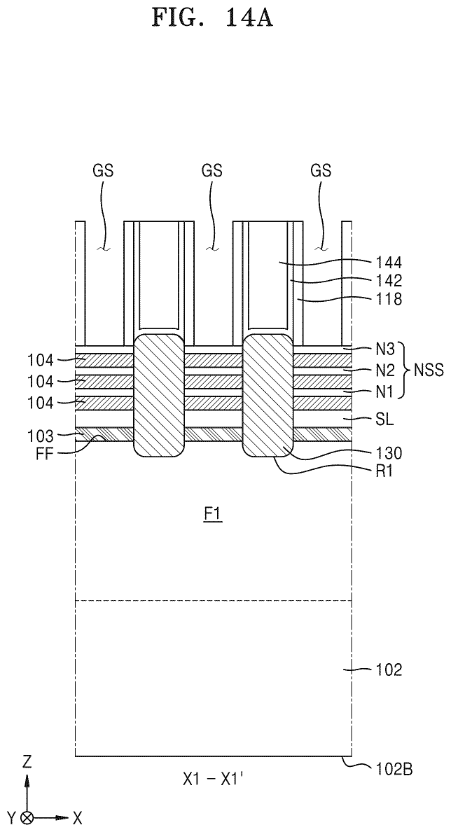

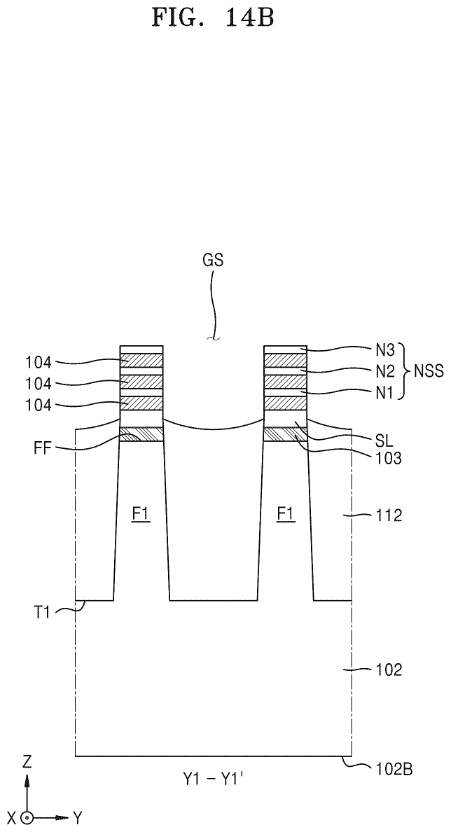

Referring to FIGS. 14A and 14B, the dummy gate layer D124 and the dummy oxide film D122 may be removed from the resulting product of FIGS. 13A, 13B, and 13C, thereby preparing a gate space GS.

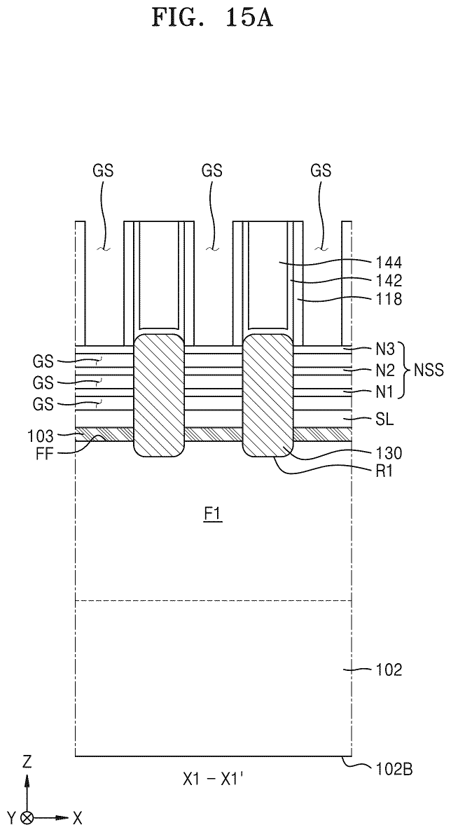

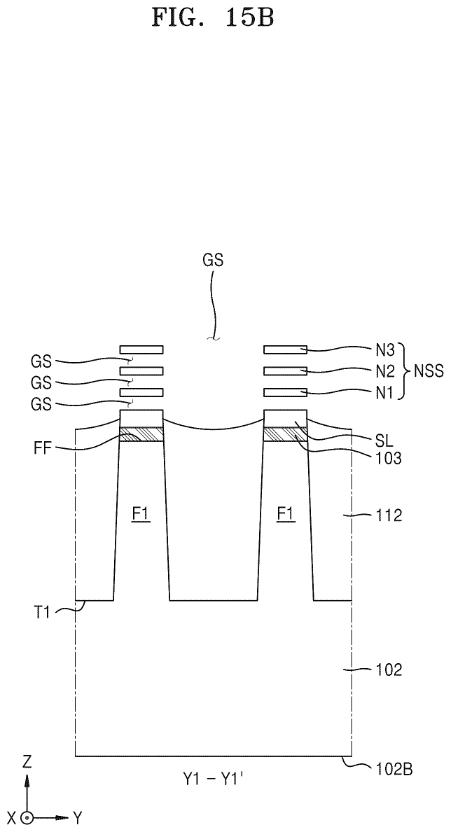

Referring to FIGS. 15A and 15B, the plurality of sacrificial semiconductor layers 104 remaining over the substrate 102 may be selectively removed from the resulting product of FIGS. 14A and 14B, thereby expanding the gate space GS to a space between each of the first to third nanosheets N1, N2, and N3 and to a space between the first nanosheet N1 and the semiconductor layer SL.

In one or more embodiments, to selectively remove the plurality of sacrificial semiconductor layers 104, a difference in etch selectivity between each of the plurality of sacrificial semiconductor layers 104 and each of the semiconductor layer SL and the first to third nanosheets N1, N2, and N3 may be used. To selectively remove the plurality of sacrificial semiconductor layers 104, a liquid-phase or gas-phase etchant may be used. In one or more embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but embodiments are not limited thereto.

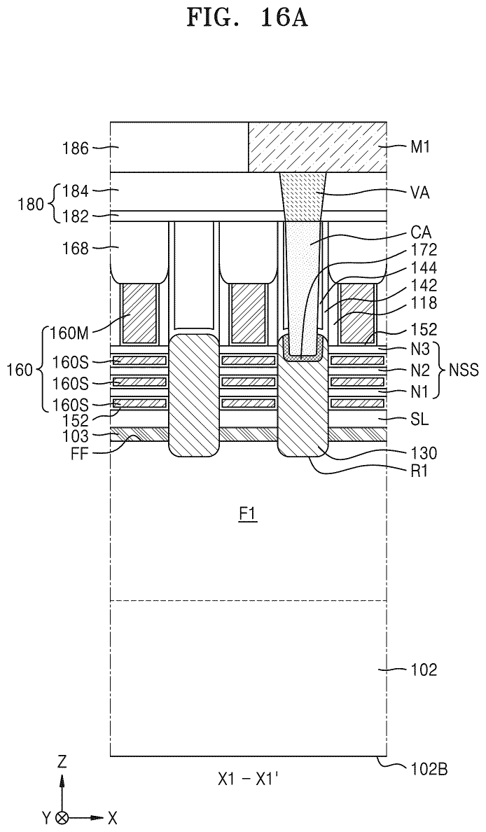

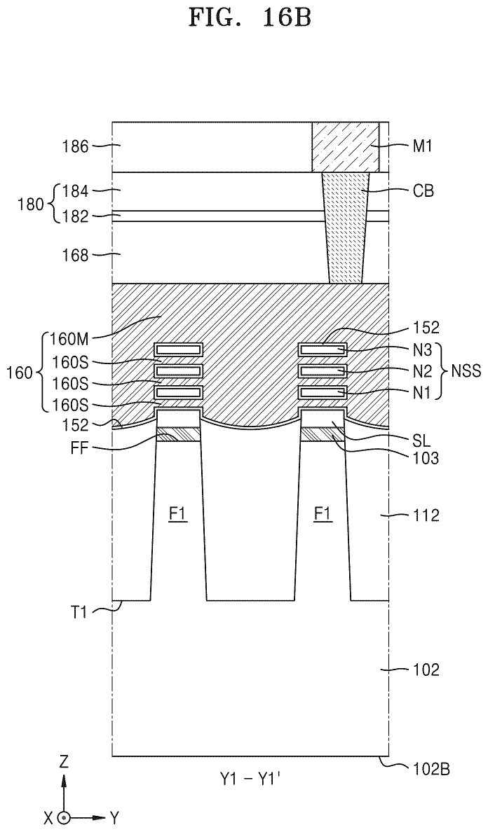

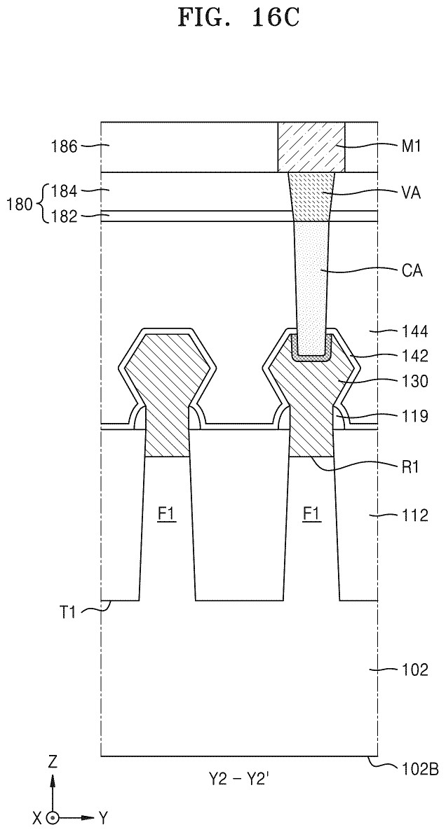

Referring to FIGS. 16A, 16B, and 16C, in the resulting product of FIGS. 15A and 15B, the gate dielectric film 152 may be formed to cover respective exposed surfaces of the semiconductor layer SL and the first to third nanosheets N1, N2, and N3. To form the gate dielectric film 152, an atomic layer deposition (ALD) process may be used.

Next, the gate line 160 may be formed on the gate dielectric film 152 to fill the gate space GS (see FIGS. 15A and 15B). Next, each of the gate line 160, the gate dielectric film 152, and the insulating spacer 118 may be partially removed from the upper surface thereof to reduce the height thereof, and the plurality of capping insulating patterns 168 may each be formed to cover the upper surface of each of the gate line 160, the gate dielectric film 152, and the insulating spacer 118.

Next, a source/drain contact hole may be formed between two adjacent gate lines 160 from among the plurality of gate lines 160 to expose the source/drain region 130, followed by forming the metal silicide film 172 on the surface of the source/drain region 130 through the source/drain contact hole, and then, the source/drain contact CA may be formed on the metal silicide film 172 to fill the source/drain contact hole.

Next, the etch stop film 182 and the upper insulating film 184 may be formed to cover the upper surface of each of the source/drain contact CA, the plurality of capping insulating patterns 168, and the inter-gate dielectric 144, thereby forming the upper insulating structure 180. Next, the source/drain via contact VA, which passes through the upper insulating structure 180 in the vertical direction (the Z direction) to be connected to the source/drain contact CA, and the gate contact CB, which passes through the upper insulating structure 180 and the capping insulating pattern 168 in the vertical direction (the Z direction) to be connected to the gate line 160, may be formed. The source/drain via contact VA and the gate contact CB may be simultaneously formed or may be respectively formed by separate processes. Next, a frontside interlayer dielectric 186, which covers the upper insulating structure 180, and the plurality of upper wiring layers M1, which pass through the frontside interlayer dielectric 186, may be formed. The plurality of upper wiring layers M1 may include an upper wiring layer M1 connected to the source/drain via contact VA and an upper wiring layer M1 connected to the gate contact CB. Next, a frontside wiring structure may be formed on the frontside interlayer dielectric 186 and the plurality of upper wiring layers M1.

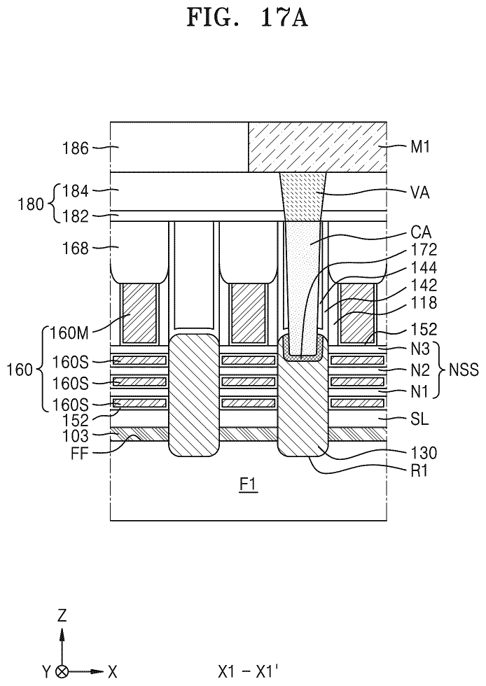

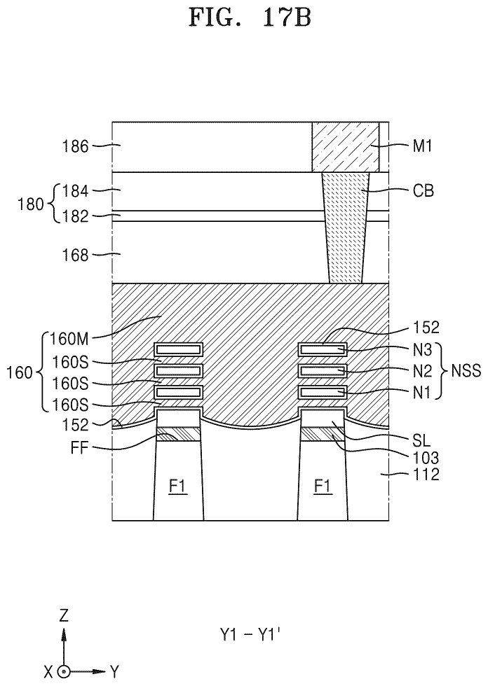

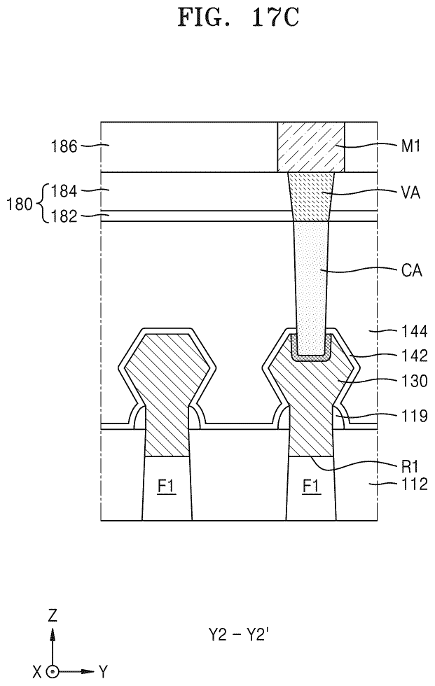

Referring to FIGS. 17A, 17B, and 17C, in the resulting product of FIGS. 16A, 16B, and 16C, the plurality of fin-type active regions F1 and the device isolation film 112 may be exposed by removing the substrate 102 from the backside surface 102B of the substrate 102, and a portion of each of the device isolation film 112 and the plurality of fin-type active regions F1, which are exposed, may be further removed, thereby reducing the thickness of each of the device isolation film 112 and the plurality of fin-type active regions F1 in the vertical direction (the Z direction).

In one or more embodiments, to remove the substrate 102 and remove the portion of each of the device isolation film 112 and the plurality of fin-type active regions F1, at least one process among a mechanical grinding process, a chemical mechanical polishing (CMP) process, a wet etching process, and a combination thereof may be used.

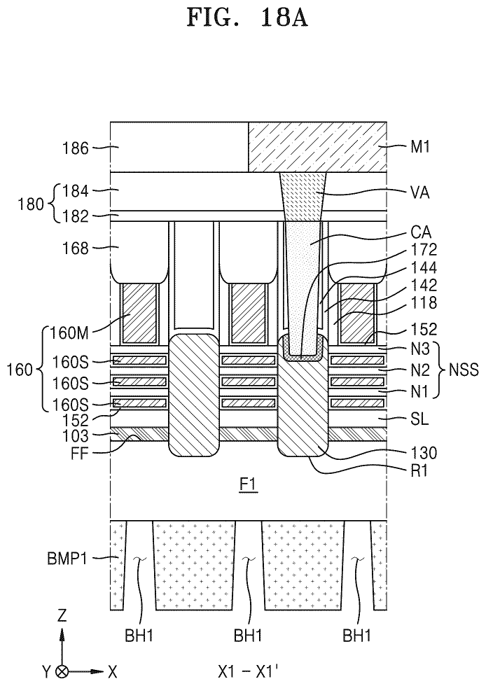

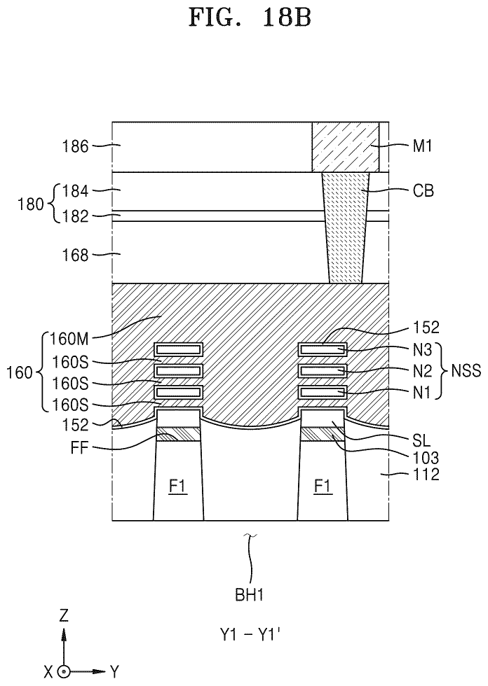

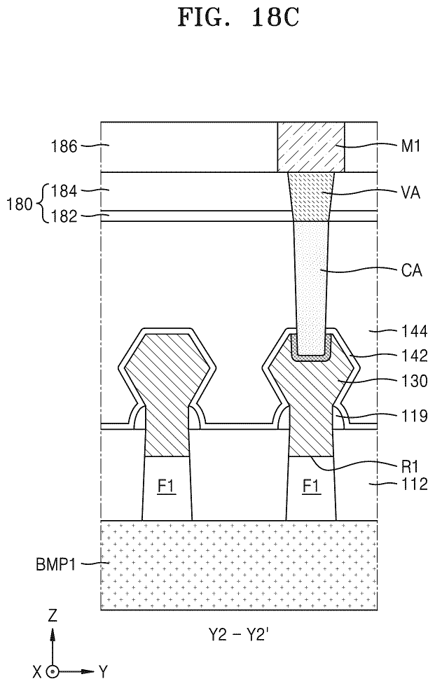

Referring to FIGS. 18A, 18B, and 18C, in the resulting product of FIGS. 17A, 17B, and 17C, a first backside mask pattern BMP1 may be formed on a backside surface at which the plurality of fin-type active regions F1 and the device isolation film 112 are exposed. The first backside mask pattern BMP1 may have a plurality of line-shaped openings BH1 extending lengthwise in the second horizontal direction (the Y direction). Each of the device isolation film 112 and the plurality of fin-type active regions F1 may be partially exposed by the plurality of line-shaped openings BH1 of the first backside mask pattern BMP1. In one or more embodiments, the first backside mask pattern BMP1 may include, but is not limited to, a spin-on-hardmask (SOH) material.

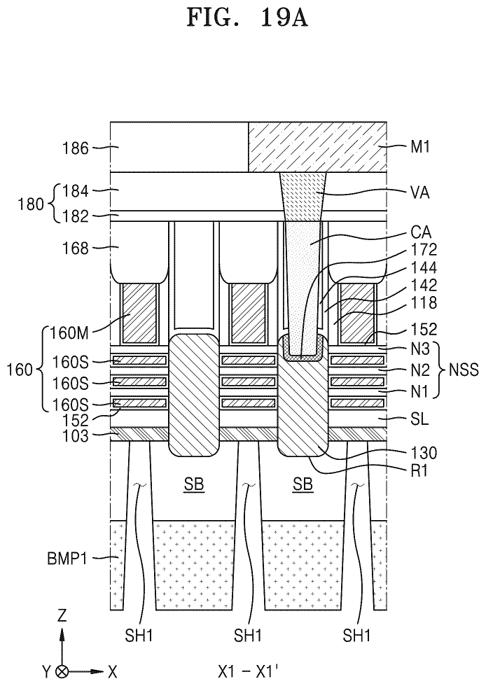

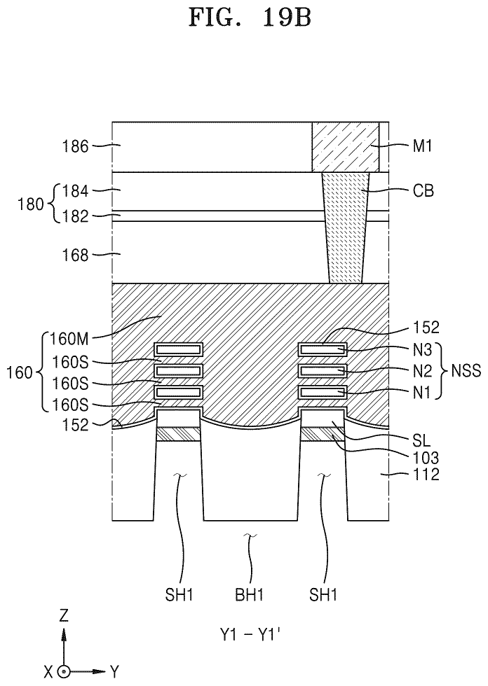

Referring to FIGS. 19A and 19B, in the resulting product of FIGS. 18A, 18B, and 18C, the plurality of fin-type active regions F1 may be selectively etched by using the first backside mask pattern BMP1 as an etch mask, thereby forming a plurality of first vertical holes SH1, which each expose the blocking sacrificial semiconductor layer 103. As the plurality of first vertical holes SH1 are formed, each of the plurality of fin-type active regions F1 may be divided into a plurality of semiconductor blocks SB.

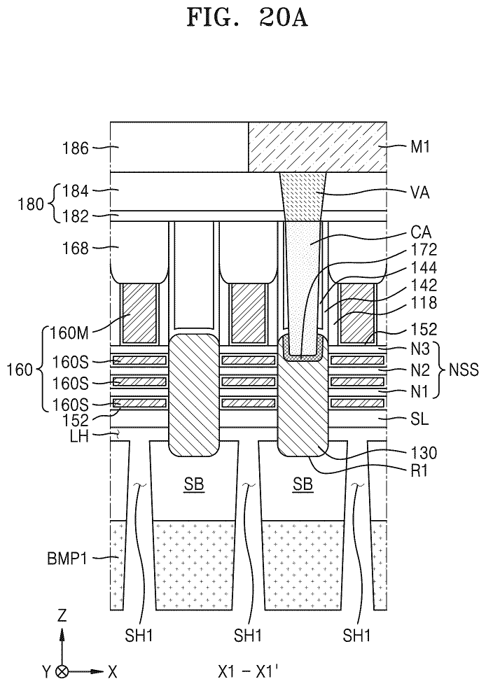

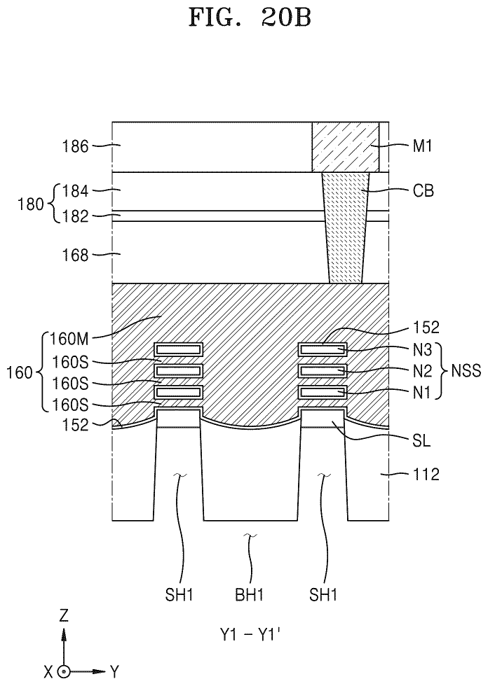

Referring to FIGS. 20A and 20B, the blocking sacrificial semiconductor layer 103, which is exposed by the plurality of first vertical holes SH1, may be removed from the resulting product of FIGS. 19A and 19B, thereby forming a horizontal hole LH, which extends from an end of each of the plurality of first vertical holes SH1 toward the source/drain region 130 adjacent thereto in the first horizontal direction (the X direction). The horizontal hole LH may be connected to a first vertical hole SH1, and the semiconductor layer SL and the source/drain region 130 may be exposed by the horizontal hole LH. In addition, portions of the semiconductor layer SL may be exposed by the plurality of first vertical holes SH1.

In one or more embodiments, to remove the blocking sacrificial semiconductor layer 103, a wet etching process may be performed. When each of the source/drain region 130 and the blocking sacrificial semiconductor layer 103 includes a SiGe layer, the blocking sacrificial semiconductor layer 103 may be formed such that the Ge content in the blocking sacrificial semiconductor layer 103 is greater than the Ge content at the outermost surface of the source/drain region 130, in the process described with reference to FIGS. 9A and 9B. As such, etch selectivity due to the difference in Ge content may be used when the blocking sacrificial semiconductor layer 103 is removed, and the source/drain region 130 may be prevented from being consumed or damaged while the blocking sacrificial semiconductor layer 103 is being removed.

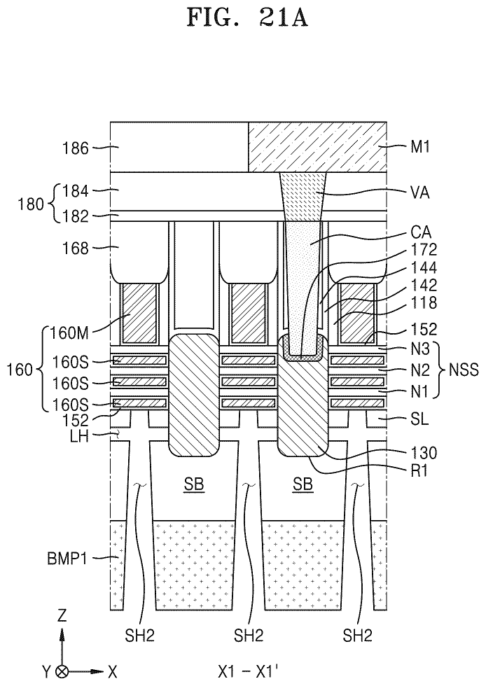

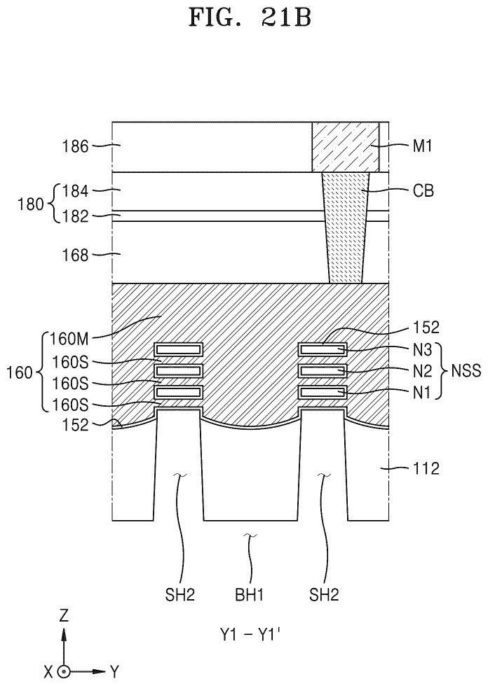

Referring to FIGS. 21A and 21B, in the resulting product of FIGS. 20A and 20B, the semiconductor layer SL may be etched through the plurality of first vertical holes SH1 by an anisotropic etching process, thereby exposing the gate dielectric film 152. As a result, a plurality of second vertical holes SH2 may be formed to have further increased lengths in the vertical direction (the Z direction) from the lengths of the plurality of first vertical holes SH1, and the gate dielectric film 152 may be exposed by the plurality of second vertical holes SH2.

Because the semiconductor layer SL has a relatively small thickness in the vertical direction (the Z direction), the anisotropic etching process for forming the plurality of second vertical holes SH2 by etching the semiconductor layer SL may be performed at a level of a trimming etching process. Therefore, while the anisotropic etching process for forming the plurality of second vertical holes SH2 by etching the semiconductor layer SL is being performed, the gate dielectric film 152 that is exposed may be prevented from being consumed or damaged.

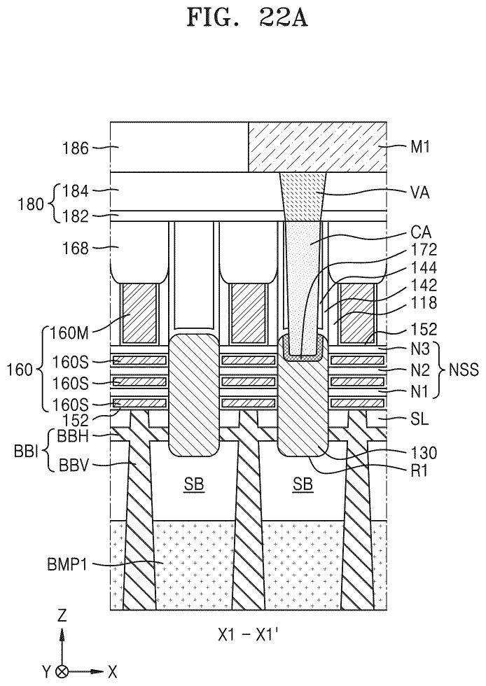

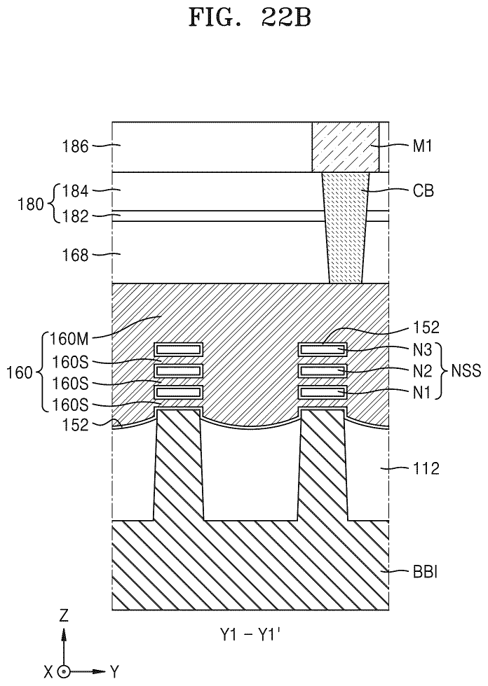

Referring to FIGS. 22A and 22B, in the resulting product of FIGS. 21A and 21B, a backside bulk insulating film BBI may be formed to fill the plurality of line-shaped openings BH1, the plurality of second vertical holes SH2, and a plurality of horizontal holes LH. In one or more embodiments, to form the backside bulk insulating film BBI, an ALD process or a chemical vapor deposition (CVD) process may be used, but embodiments are not limited thereto.

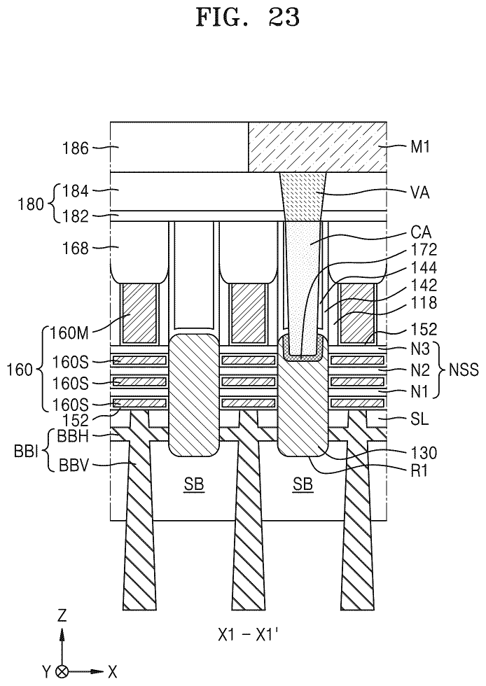

Referring to FIG. 23, the first backside mask pattern BMP1 may be removed from the resulting product of FIGS. 22A and 22B. When the first backside mask pattern BMP1 includes an SOH material, ashing and strip processes may be used to remove the first backside mask pattern BMP1.

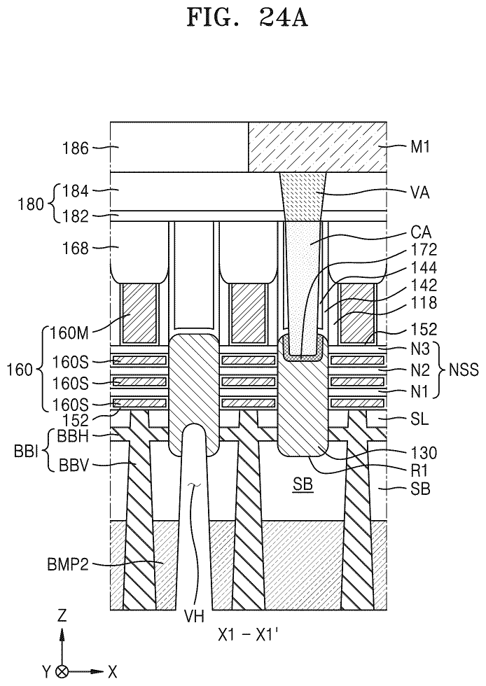

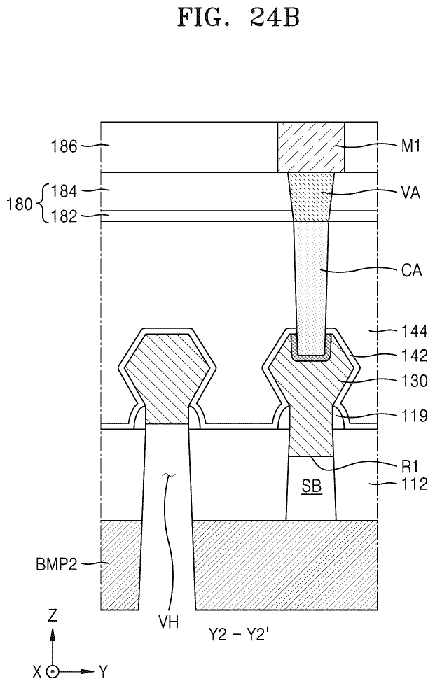

Referring to FIGS. 24A and 24B, a planarized hardmask film may be formed by coating an SOH material on a resulting product obtained by performing the process described with reference to FIG. 23, and the hardmask film may be patterned, thereby forming a second backside mask pattern BMP2, which has a hole exposing the semiconductor block SB. Next, the semiconductor block SB may be etched by using the second backside mask pattern BMP2 as an etch mask, thereby forming a via hole VH, which exposes the source/drain region 130. The source/drain region 130 may be partially etched while the via hole VH is being formed, and thus, the via hole VH may extend to the inside of the source/drain region 130.

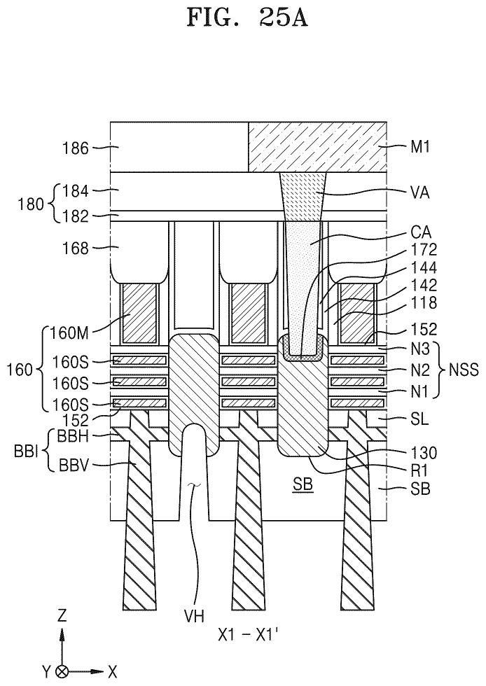

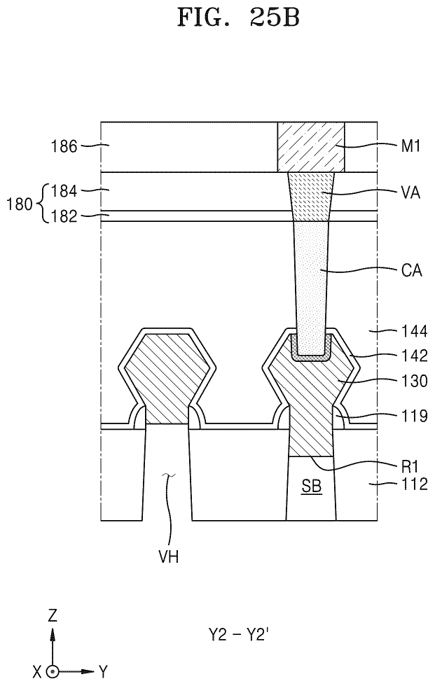

Referring to FIGS. 25A and 25B, the second backside mask pattern BMP2 may be removed from the resulting product of FIGS. 24A and 24B. When the second backside mask pattern BMP2 includes an SOH material, ashing and strip processes may be used to remove the second backside mask pattern BMP2.

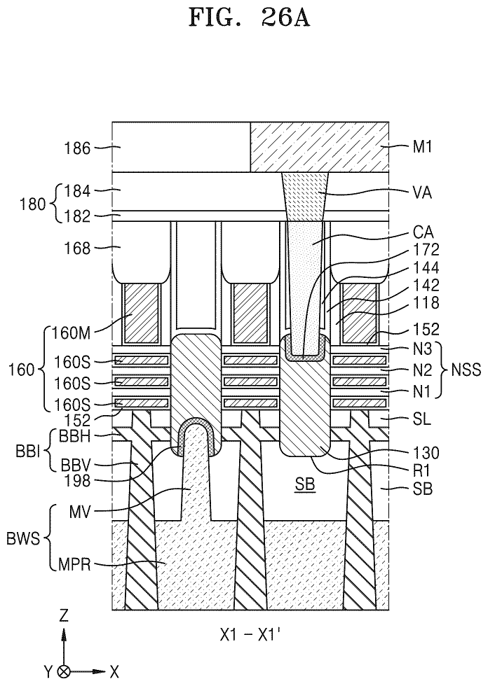

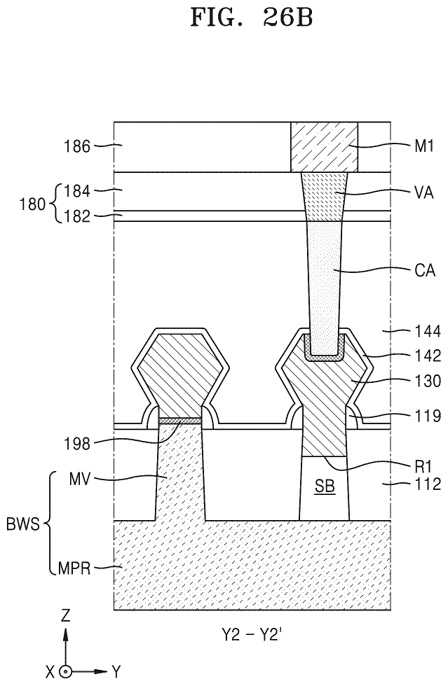

Referring to FIGS. 26A and 26B, in the resulting product of FIGS. 25A and 25B, a conductive material may fill the via hole VH and a space between the respective backside bulk insulating films BBI, thereby forming the backside via contact MV and the backside power rail MPR, which are shown in FIGS. 3A to 3C.

Heretofore, although the example of the method of fabricating the integrated circuit device 100 shown in FIGS. 2, 3A to 3C, and 4 has been described with reference to FIGS. 9A to 26B, it will be understood that the integrated circuit devices 200, 300, 400, and 500 respectively shown in FIGS. 5 to 8 and integrated circuit devices having various structures modified and changed therefrom may be fabricated by making various modifications and changes to the example described with reference to FIGS. 9A to 26B without departing from the spirit and scope of the disclosure.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An integrated circuit device comprising:
a first gate line and a second gate line adjacent to each other in a first horizontal direction and extending in a second horizontal direction that is perpendicular to the first horizontal direction;
a source/drain region between the first gate line and the second gate line;
a backside via contact connected to the source/drain region; and
a first backside bulk insulating film and a second backside bulk insulating film, wherein, in the first horizontal direction, the backside via contact is between the first backside bulk insulating film and the second backside bulk insulating film,
wherein each of the first backside bulk insulating film and the second backside bulk insulating film comprises:
a vertical insulating portion below one gate line among the first gate line and the second gate line in a vertical direction and extending in the vertical direction, the vertical insulating portion comprising a portion facing the backside via contact in the first horizontal direction; and
a horizontal insulating portion protruding from a sidewall of the vertical insulating portion in the first horizontal direction and contacting the source/drain region.

2. The integrated circuit device of claim 1, further comprising a first gate dielectric film and a second gate dielectric film respectively surrounding the first gate line and the second gate line,
wherein the vertical insulating portion of the first backside bulk insulating film and the vertical insulating portion of the second backside bulk insulating film respectively contact the first gate dielectric film and the second gate dielectric film.

3. The integrated circuit device of claim 1, further comprising a backside power rail connected to the backside via contact and spaced apart from the source/drain region in the vertical direction,
wherein the vertical insulating portion of the first backside bulk insulating film and the vertical insulating portion of the second backside bulk insulating film contact the backside power rail.

4. The integrated circuit device of claim 1, further comprising a semiconductor block at least partially covering a sidewall of the backside via contact in the first horizontal direction.

5. The integrated circuit device of claim 1, further comprising a device isolation film at least partially covering a sidewall of the backside via contact in the second horizontal direction.

6. The integrated circuit device of claim 1, further comprising a semiconductor layer between the horizontal insulating portion of the first backside bulk insulating film and the first gate line, and between the horizontal insulating portion of the second backside bulk insulating film and the second gate line,
wherein the semiconductor layer at least partially covers a sidewall of the vertical insulating portion of the first backside bulk insulating film and the vertical insulating portion of the second backside bulk insulating film in the first horizontal direction.

7. The integrated circuit device of claim 1, further comprising:
a semiconductor layer between the horizontal insulating portion of the first backside bulk insulating film and the first gate line, and between the horizontal insulating portion of the second backside bulk insulating film and the second gate line, the semiconductor layer at least partially covering a sidewall of the vertical insulating portion of the first backside bulk insulating film and the vertical insulating portion of the second backside bulk insulating film in the first horizontal direction; and
a first nanosheet stack and a second nanosheet stack respectively over the vertical insulating portion of the first backside bulk insulating film and the vertical insulating portion of the second backside bulk insulating film,
wherein each of first nanosheet stack and the second nanosheet stack comprises a plurality of nanosheets spaced apart from each other in the vertical direction and surrounded by one gate line among the first gate line and the second gate line, and
wherein, in the vertical direction, a thickness of the semiconductor layer is greater than a thickness of each of the plurality of nanosheets.

8. The integrated circuit device of claim 1, further comprising:
a semiconductor layer between the horizontal insulating portion of the first backside bulk insulating film and the first gate line, and between the horizontal insulating portion of the second backside bulk insulating film and the second gate line, the semiconductor layer at least partially coverings a sidewall of the vertical insulating portion of the first backside bulk insulating film and the vertical insulating portion of the second backside bulk insulating film in the first horizontal direction; and
a first nanosheet stack and a second nanosheet stack respectively over the vertical insulating portion of the first backside bulk insulating film and the vertical insulating portion of the second backside bulk insulating film,
wherein each of first nanosheet stack and the second nanosheet stack comprises a plurality of nanosheets spaced apart from each other in the vertical direction and surrounded by one gate line among the first gate line and the second gate line, and
wherein, in the vertical direction, a thickness of the semiconductor layer is equal to or less than a thickness of each of the plurality of nanosheets.

9. The integrated circuit device of claim 1, further comprising:
a first nanosheet stack comprising a plurality of first nanosheets spaced apart from each other in the vertical direction and surrounded by the first gate line; and
a second nanosheet stack comprising a plurality of second nanosheets spaced apart from each other in the vertical direction and surrounded by the second gate line,
wherein the first gate line comprises a plurality of first sub-gate portions respectively covering the plurality of first nanosheets,
wherein the second gate line comprises a plurality of second sub-gate portions respectively covering the plurality of second nanosheets, and
wherein in the vertical direction, a thickness of the horizontal insulating portion of the first backside bulk insulating film and a thickness of the horizontal insulating portion of the second backside bulk insulating film are greater than a thickness of each of the plurality of first sub-gate portions and the plurality of second sub-gate portions.

10. The integrated circuit device of claim 1, further comprising:
a first nanosheet stack comprising a plurality of first nanosheets spaced apart from each other in the vertical direction and surrounded by the first gate line; and
a second nanosheet stack comprising a plurality of second nanosheets spaced apart from each other in the vertical direction and surrounded by the second gate line,
wherein, in the vertical direction, a thickness of the horizontal insulating portion of the first backside bulk insulating film is greater than a distance between the vertical insulating portion of the first backside bulk insulating film and a nanosheet among the plurality of first nanosheets closest to the vertical insulating portion of the first backside bulk insulating film, and
wherein, in the vertical direction, a thickness of the horizontal insulating portion of the second backside bulk insulating film is greater than a distance between the vertical insulating portion of the second backside bulk insulating film and a nanosheet among the plurality of second nanosheets closest to the vertical insulating portion of the second backside bulk insulating film.

11. An integrated circuit device comprising:
a first source/drain region and a second source/drain region adjacent to each other in a first horizontal direction;
a plurality of nanosheets between the first source/drain region and the second source/drain region, each of the plurality of nanosheets being spaced apart from each other in a vertical direction being connected to the first source/drain region and the second source/drain region;
a gate line extending in a second horizontal direction between the first source/drain region and the second source/drain region and surrounding the plurality of nanosheets, the second horizontal direction being perpendicular to the first horizontal direction;
a gate dielectric film between the plurality of nanosheets and the gate line and surrounding the gate line;
a backside via contact connected to the first source/drain region; and
a backside bulk insulating film between the first source/drain region and the second source/drain region and spaced apart from the gate line in the vertical direction;
wherein the gate dielectric film is between the backside bulk insulating film and the gate line in the vertical direction, and
wherein the backside bulk insulating film comprises:
a vertical insulating portion below the gate line in the vertical direction and extending in the vertical direction, the vertical insulating portion comprising a portion facing the backside via contact in the first horizontal direction; and
a first horizontal insulating portion and a second horizontal insulating portion respectively protruding from a first sidewall and a second sidewall of the vertical insulating portion in the first horizontal direction.

12. The integrated circuit device of claim 11, wherein the first horizontal insulating portion contacts the first source/drain region, and
wherein the second horizontal insulating portion contacts the second source/drain region.

13. The integrated circuit device of claim 11, wherein, in the first horizontal direction, a width of the vertical insulating portion of the backside bulk insulating film is less than a width of each of the plurality of nanosheets.

14. The integrated circuit device of claim 11, wherein the vertical insulating portion of the backside bulk insulating film contacts the gate dielectric film.

15. The integrated circuit device of claim 11, further comprising a backside power rail connected to the backside via contact and spaced apart from the first source/drain region in the vertical direction with the backside via contact therebetween,
wherein the vertical insulating portion of the backside bulk insulating film comprises a portion contacting the backside power rail.

16. The integrated circuit device of claim 11, further comprising:
a semiconductor block at least partially covering a first sidewall of the backside via contact in the first horizontal direction; and
a device isolation film at least partially covering a second sidewall of the backside via contact in the second horizontal direction.

17. The integrated circuit device of claim 11, further comprising a semiconductor layer between the first horizontal insulating portion and the second horizontal insulating portion of the backside bulk insulating film and the gate dielectric film, the semiconductor layer at least partially covering a sidewall of the vertical insulating portion of the backside bulk insulating film in the first horizontal direction.

18. An integrated circuit device comprising:
a plurality of backside bulk insulating films arranged in a line in a first horizontal direction and each extending in a second horizontal direction that is perpendicular to the first horizontal direction;
a plurality of nanosheet stacks respectively spaced apart from the plurality of backside bulk insulating films in a vertical direction, each of the plurality of nanosheet stacks comprising a plurality of nanosheets;
a plurality of gate lines extending in the second horizontal direction and respectively surrounding the plurality of nanosheets;
a plurality of source/drain regions respectively between the plurality of gate lines, each of the plurality of source/drain regions contacting the plurality of nanosheets of an adjacent nanosheet stack among the plurality of nanosheet stacks;
a plurality of backside wiring structures respectively between the plurality of backside bulk insulating films; and
a plurality of gate dielectric films respectively surrounding the plurality of gate lines,
wherein each of the plurality of backside bulk insulating films comprises:
a vertical insulating portion contacting adjacent backside wiring structures among the plurality of backside wiring structures, the vertical insulating portion extending in the vertical direction toward respective gate line from the plurality of gate lines; and
a first horizontal insulating portion and a second horizontal insulating portion respectively protruding from a first sidewall and a second sidewall of the vertical insulating portion in the first horizontal direction, and
wherein each of the plurality of backside bulk insulating films comprises a nitrogen-containing insulating film.

19. The integrated circuit device of claim 18, wherein each of the plurality of backside wiring structures comprises:
a backside via contact extending in the vertical direction between adjacent backside bulk insulating films among the plurality of backside bulk insulating films, the backside via contact connected to a first source/drain region among the plurality of source/drain regions; and
a backside power rail extending in the second horizontal direction and connected to the backside via contact, the backside power rail being spaced apart from the first source/drain region in the vertical direction with the backside via contact therebetween, and
wherein the backside power rail contacts a respective vertical insulating portion, and
wherein the backside via contact is spaced apart from a respective vertical insulating portion in the first horizontal direction.

20. The integrated circuit device of claim 18, wherein, in each of the plurality of backside bulk insulating films, each of the horizontal insulating portions contacts an adjacent source/drain region among the plurality of source/drain regions, and
wherein each of the plurality of backside bulk insulating films comprises at least one of a silicon nitride (SiN) film, a silicon carbonitride (SiCN) film, a silicon oxycarbonitride (SiOCN) film, and a combination thereof.
